(19) United States
(12) Patent Application Publication
(10) Pub. No.: US 2015/0162265 A1
(43) Pub. Date: Jun. 11, 2015

(54) SEMICONDUCTOR PACKAGE AND METHOD OF MANUFACTURING THE SAME

(71) Applicants: Cha-Jea JO, Incheon (KR); Tae-Je CHO, Hwaseong-si (KR)

(72) Inventors: Cha-Jea JO, Incheon (KR); Tae-Je CHO, Hwaseong-si (KR)

(21) Appl. No.: 14/450,723

(22) Filed: Aug. 4, 2014

(30) Foreign Application Priority Data
Dec. 6, 2013 (KR) 10-2013-0151434

(51) Int. Cl. H01L 23/48

(52) U.S. Cl. CPC H01L 23/481

(57) ABSTRACT

Semiconductor packages including chips having through silicon vias (TSVs) and methods of manufacturing the same may be provided to provide reliable and thinner semiconductor packages by mitigating or preventing a crack from occurring at an uppermost chip. The semiconductor package including a substrate, a first chip stacked on the substrate, the first chip including a plurality of through silicon vias (TSVs), an uppermost chip stacked on the first chip, the uppermost chip being thicker than the first chip, a first gap fill portion covering at least a portion of a side surface of the uppermost chip while filling a space between the first chip and the uppermost chip, and a sealant for sealing the first chip, the uppermost chip, and the first gap fill portion may be provided.

### CROSS-REFERENCE TO RELATED APPLICATIONS

This application claims the benefit of Korean Patent Application No. 10-2013-0151434, filed on Dec. 6, 2013, in the Korean Intellectual Property Office, the disclosure of which is incorporated herein in its entirety by reference.

### BACKGROUND

The inventive concepts relate to semiconductor packages, and more particularly, to semiconductor packages having a chip including a through silicon via (TSV) and methods of manufacturing the semiconductor packages.

In general, various semiconductor processes are performed on a wafer to form a plurality of semiconductor chips. Then, a packaging process is performed on the wafer such that semiconductor chips are mounted on a printed circuit board (PCB), and thus, a plurality of semiconductor packages are formed. The resultant semiconductor package may include a semiconductor chip, a PCB on which the semiconductor chip is mounted, a bonding wire or bump for electrically connecting the semiconductor chip and the PCB, and a sealant for sealing the semiconductor chip.

Recently, as integration density of semiconductor chips increases, chip sizes of the semiconductor chips decrease, thereby decreasing sizes of semiconductor packages including the same. For example, a semiconductor chip-sized chip scale package (CSP) and a wafer level package (WLP) have been developed to reduce sizes of semiconductor packages. Further, a package on package (POP), in which a package is stacked on a package, and a system on chip (SOC) or a system in package (SIP), in which the entire system is included in a single chip or a single package, also have been developed.

### SUMMARY

Some of the inventive concepts provide highly reliable and thinner semiconductor packages including chips having through silicon vias (TSVs), which mitigate or prevent a crack from occurring at an uppermost chip.

Some of the inventive concepts also provide methods of manufacturing the semiconductor packages.

According to an example embodiment of the inventive concepts, a semiconductor package includes a substrate, a first chip stacked on the substrate, the first chip including a plurality of through silicon vias (TSVs), an uppermost chip stacked on the first chip, a thickness of the uppermost chip being larger than that of the first chip, a first gap fill portion covering at least a portion of a side surface of the uppermost chip while filling a space between the first chip and the uppermost chip, and a sealant for sealing the first chip, the uppermost chip, and the first gap fill portion.

The first gap fill portion may cover at least a portion of a side surface of the first chip (e.g., a portion of a side surface of the first chip or an entire side surface of the first chip).

The first gap fill portion may not cover or exist on an upper surface of the uppermost chip.

The first gap fill portion may include a nonconductive adhesive or nonconductive tape having a fluxing function.

The semiconductor package may further include a plurality of pads on an upper surface of the first chip, the plurality of pads electrically connected to the TSVs, and a plurality of connection members disposed on a lower surface of the uppermost chip, the plurality of connection members coupled to the plurality of pads. The first gap fill portion may fill a space between the plurality of connection members.

The uppermost chip may not include a TSV.

An upper surface of the uppermost chip may be exposed by the sealant.

A horizontal cross section of the first chip may be larger than that of the uppermost chip, and the first gap fill portion may cover an upper surface of an edge portion of the first chip, and the edge portion may protrude from the side surface of the uppermost chip.

The first chip may be stacked on the substrate through a substrate connection member, and a space between the first chip and the substrate may be filled with at least one of an underfill and the sealant.

The semiconductor package may further include at least one second chip disposed between the first chip and the uppermost chip, the at least one second chip including a plurality of TSVs.

A space between the first chip and the second chip may be filled with a second gap fill portion, and the second gap fill portion may cover at least a portion of at least one of a side surface of the first chip and a side surface of the at least one second chip (e.g., a portion of the side surface or an entire side surface of the at least one second chip).

The semiconductor package may further include a thermal interface material (TIM) and a heat sink on an upper surface of the uppermost chip, the upper surface of the uppermost chip exposed by the sealant.

According to an example embodiment of the inventive concepts, a semiconductor package may include a first chip including a plurality of through silicon vias (TSVs), a plurality of first connection members on a lower surface of the first chip and electrically connected to the TSVs, an uppermost chip stacked on the first chip, a second connection member on a lower surface of the uppermost chip and coupled to the TSVs, a thickness of the uppermost chip being larger than that of the first chip, a first gap fill portion covering at least a portion of a side surface of the uppermost chip while filling a space between the first chip and the uppermost chip, and a sealant for sealing the first chip, the uppermost chip, and the first gap fill portion.

A horizontal cross section of the first chip may be larger than that of the uppermost chip, the first gap fill portion may cover an upper surface of an edge portion of the first chip, and the edge portion may protrude from the side surface of the uppermost chip.

An upper surface of the uppermost chip may be exposed by the sealant, the sealant covering at least a portion of at least one of the side surface of the uppermost chip (e.g., a portion of a side surface of the first chip or an entire side surface of the first chip), and a lower surface of the sealant may form substantially a same plane as a lower surface of the first chip.

The semiconductor package may further include at least one second chip disposed between the first chip and the uppermost chip, the at least one second chip including a plurality of TSVs, wherein a space between the first chip and the second chip is filled with a second gap fill portion, and the second gap fill portion covers at least a portion of at least one of a side surface of the first chip and a side surface of the at least one second chip.

The semiconductor package may further include a base substrate including an external connection member on a lower surface thereof, the base substrate having the first chip and the uppermost chip mounted thereon through the plurality of first connection members.

A size of the base substrate may be larger than that of the first chip, and a lower surface of the sealant may be joined onto an edge portion of the base substrate.

The base substrate may be any one of a printed circuit board (PCB), an interposer, and a semiconductor chip.

According to an example embodiment of the inventive concepts, a method of manufacturing a semiconductor package may include preparing a first wafer including a plurality of first chips, each of the plurality of first chips including a plurality of through silicon vias (TSVs) and a plurality of first connection members, the plurality of first connection members on a lower surface of the each of the plurality of first chips and connected to the TSVs, preparing a second wafer including a plurality of second chips, each of the plurality of second chip not including a TSV but including a plurality of second connection members, the plurality of second connection members disposed on a lower surface of the each of the plurality of second chips, separating the plurality of first chips of the first wafer into individual first chips and separating the plurality of second chips of the second wafer into individual second chips, stacking at least one individual first chip on a substrate, forming a stacked structure by stacking at least one individual second chip on the at least one individual first chip stacked on the substrate, and sealing the stacked structure with a sealant. While forming a stacked structure, a gap fill material layer may be overflowed between the at least one individual first chip to cover at least a portion of a side surface of the second chip.

The method may further include, after the preparing of the second wafer, coating the gap fill material layer having a fluxing function on the second wafer to cover the plurality of second connection members.

The method may further include forming a plurality of stacked structures on the substrate including the forming a stacked structure, sealing the plurality of stacked structures including the sealing the stacked structure, and dividing, after the sealing, the sealed plurality of stacked structures into individual packages each including at least one stacked structure.

The sealing of the stacked structure may include one of sealing the stacked structure to expose an upper surface of an uppermost chip and grinding the uppermost chip and the sealant after sealing the stacked structure to cover the upper surface of the uppermost chip.

The method may further include, after the stacking of at least one individual first chip on the substrate, further stacking one or more individual first chips on the stacked first chip, wherein the forming a stacked structure includes forming a stacked structure by stacking the second chip on an uppermost one of the stacked first chips.

According to an example embodiment of the inventive concepts, a method of manufacturing a semiconductor package includes preparing a wafer including a plurality of first chips each including a plurality of through silicon vias (TSVs), forming a plurality of stacked structures by stacking a plurality of uppermost chips on upper surfaces of corresponding first chips, each of the uppermost chips being thicker than a corresponding one of the first chips, sealing the plurality of stacked structures on the wafer by using an internal sealant, dividing the sealed plurality of stacked structures into individual intermediate packages each including one stacked structure, stacking at least one of the intermediate packages on a substrate, sealing the at least one intermediate package with an external sealant. While forming the plurality of stacked structures, a gap fill material layer may be overflowed between each of the uppermost chips and a corresponding one of first chips and and may cover at least a portion of a side surface of the uppermost chip.

According to an example embodiment of the inventive concepts, a semiconductor package includes first chips stacked on each other, each of the first chips including a plurality of through silicon vias (TSVs), at least one second chip on the first chips, a gap fill portion covering at least a portion of a side surface of the at least one second chip and not covering an upper surface of the at least one second chip, and a sealant for sealing the first chips, the at least one second chip, and the gap fill portion.

The at least one second chip may be thicker than one of the first chips immediately below.

The at least one second chip may have a cut-out shaped upper surface, and the cut-out shaped upper surface may be configured to be coplanar with an upper surface of the sealant and exposed by the sealant.

The semiconductor package may further include a heat sink coupled to the at least one second chip on an upper surface thereof.

A horizontal cross section of some of the first chips may be larger than that of the at least one second chip.

### BRIEF DESCRIPTION OF THE DRAWINGS

FIG. 1 is a cross-sectional view of a semiconductor package according to an example embodiment of the inventive concepts;

FIGS. 2 through 15 are cross-sectional views of semiconductor packages each having a structure that is different from that of the semiconductor package of FIG. 1, according to other example embodiments of the inventive concepts;

FIG. 16 is a cross-sectional view showing in more detail a chip including a TSV, which is used for the semiconductor packages of FIGS. 1 through 15;

FIG. 17A is a perspective view showing a first wafer including a plurality of chips, each of which includes a TSV;

FIG. 17B is a perspective view showing a second wafer including a plurality of uppermost chips, each of which does not include a TSV;

FIG. 18A is a cross-sectional view taken along a line I-I′ of FIG. 17A;

FIG. 18B is a cross-sectional view taken along a line II-II′ of FIG. 17B;

FIGS. 19 through 22 are cross-sectional views showing a method of manufacturing the semiconductor package of FIG. 1, according to an example embodiment of the inventive concepts;

FIG. 23 is a cross-sectional view showing a modification example of the process of FIG. 19 to implement the semiconductor package of FIG. 7, according to an example embodiment of the inventive concepts;

FIG. 24 is a cross-sectional view showing a process that is additionally performed after the process of FIG. 21 to implement the semiconductor package of FIG. 6, according to an example embodiment of the inventive concepts;

FIG. 25 is a cross-sectional view showing a modification example of the process of FIG. 20 to implement the semiconductor package of FIG. 10 or FIG. 11, according to an example embodiment of the inventive concepts;

FIG. 26 is a conceptual diagram showing a principle in which the uppermost chip, which does not include a TSV, is stacked on each chip of an wafer including chips each including a TSV, according to an example embodiment of the inventive concepts;

FIGS. 27 through 31 are cross-sectional views showing a method of manufacturing the semiconductor package of FIG. 14, according to an example embodiment of the inventive concepts;

FIG. 32 is a conceptual diagram showing an exposed molded underfill (e-MUF) process in a process of manufacturing a semiconductor package according to an example embodiment of the inventive concepts;

FIG. 33 is a cross-sectional view of a semiconductor package according to another example embodiment of the inventive concepts:

FIG. 34 is a block diagram of a memory card including a semiconductor package according to one or more example embodiments of the inventive concepts;

FIG. 35 is a block diagram of an electronic system including a semiconductor package according to one or more example embodiments of the inventive concepts; and

FIG. 36 is a perspective view of an electronic device to which a semiconductor package according to one or more example embodiments of the inventive concepts is applied;

### DETAILED DESCRIPTION OF EXAMPLE EMBODIMENTS

Hereinafter, some of the inventive concepts will be described more fully with reference to the accompanying drawings, in which various example embodiments of the inventive concepts are shown.

This present disclosure may, however, be embodied in many different forms and should not be construed as limited to the example embodiments set forth herein. Rather, these example embodiments are provided so that this disclosure will be thorough and complete, and will fully convey the scope of the inventive concepts to those of ordinary skill in the art.

Throughout the specification, it will also be understood that when an element is referred to as being “connected to” another element, it can be directly connected to the other element, or intervening elements may also be present. Similarly, it will also be understood that when an element is referred to as being “on” another element, it can be directly on the other element, or intervening elements may also be present. Also, in the drawings, the structures or sizes of the elements are exaggerated for clarity, and redundant descriptions thereof are omitted. Like reference numerals denote like elements in the drawings.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments. It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Unless otherwise defined, all terms (including technical and scientific terms) used herein are to be interpreted as is customary in the art to which the inventive concepts belong. It will be further understood that terms in common usage should also be interpreted as is customary in the relevant art and not in an idealized or overly formal sense unless expressly so defined herein. The terms used herein are for illustrative purpose of the present inventive concepts only and should not be construed to limit the meaning or the scope of the present inventive concepts as described in the claims.

Hereinafter, some example embodiments will be explained in further detail with reference to the accompanying drawings.

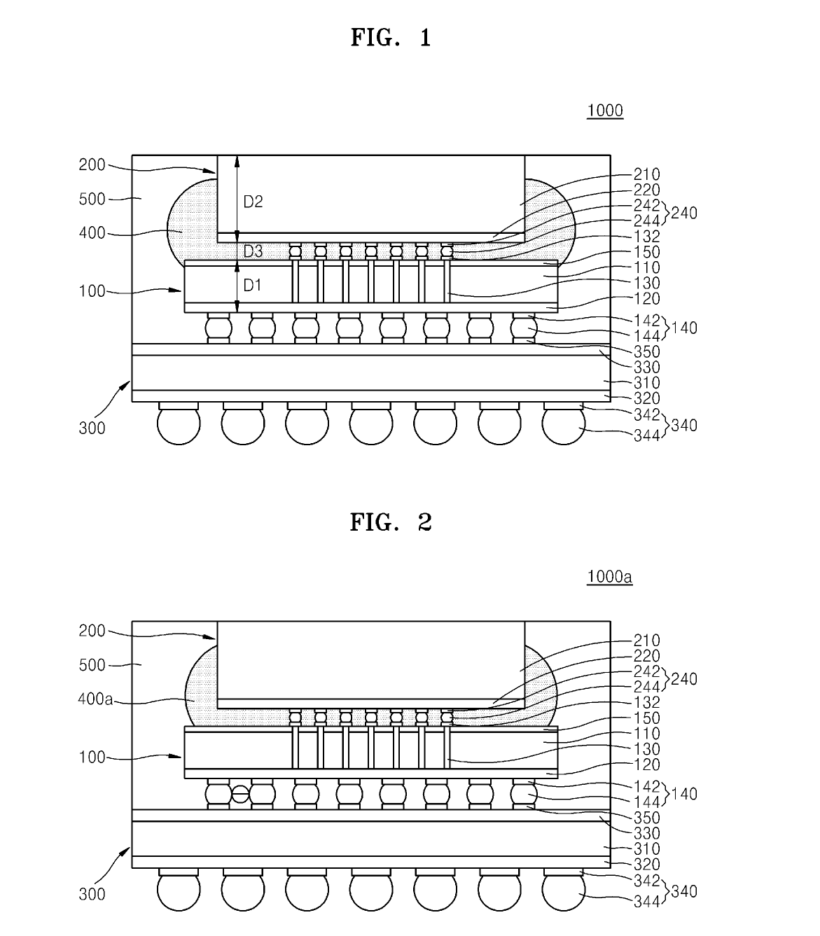

FIG. 1 is a cross-sectional view of a semiconductor package 1000 according to an embodiment of the inventive concepts.

Referring to FIG. 1, the semiconductor package 1000 may include a first chip 100, a second chip 200, a substrate 300, a gap fill portion 400, and a sealant 500.

The first chip 100 may include a body 110, an interconnection layer 120, a through silicon via (TSV) 130, a substrate connection member 140, and an upper protection layer 150. The first chip 100 may be formed on an active wafer or on an interposer substrate. The active wafer is referred to as a wafer (e.g., a silicon wafer), on which a semiconductor chip may be formed.

When the first chip 100 is formed on the active wafer, the body 110 may include, for example, a semiconductor substrate (not shown), an integrated circuit layer (not shown), and an interlayer insulating layer (not shown). The interconnection layer 120 may include, for example, an intermetallic insulating layer (not shown) and a multi-layered interconnection layer (not shown) in the intermetallic insulating layer. Although the first chip 100 is formed on the active wafer, the first chip 100 may include only a semiconductor substrate and may not include elements, such as an integrated circuit layer, an interlayer insulating layer, an intermetallic insulating layer, and the like.

The semiconductor substrate may include, for example, a IV group material wafer or a III-V group compound wafer. Also, the semiconductor wafer may be a single-crystalline wafer, for example, a single-crystalline silicon wafer, in terms of a formation method. However, the semiconductor wafer is not limited to the single-crystalline wafer. That is, various wafers, for example, an epitaxial wafer, a polished wafer, an annealed wafer, or a silicon on insulator (SOI) wafer, may be used as the semiconductor substrate. The epitaxial wafer refers to a wafer obtained by growing a crystalline material on a single-crystalline silicon wafer.

When the first chip 100 is formed on the interposer substrate, the interconnection layer 120 may be omitted. Further, the body 110 may be a support substrate formed of, for example, silicon, glass, ceramic, or plastic.

Although not illustrated, a passivation layer (not shown) may be formed on the lower surface of the interconnection layer 120. Such a passivation layer may protect the first chip 100 from external physical and/or chemical damages. The passivation layer may be, for example, an oxide layer, a nitride layer, or a double layer including, for example, an oxide layer and a nitride layer. The passivation layer may be formed of oxide or nitride, for example, silicon oxide (SiO₂), silicon nitride (SiNx), or a combination thereof, by using a High Density Plasma-Chemical Vapor Deposition (HDP-CVD) process.

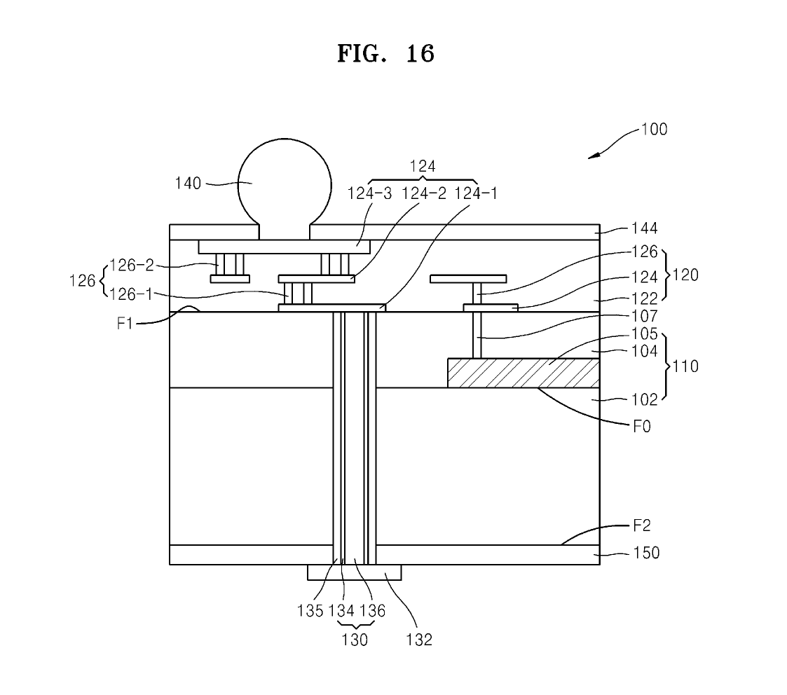

A structure of the body 110 and a structure of the interconnection layer 120 will be described in more detail with reference to FIG. 16.

The substrate connection member 140 may include a first lower pad 142 and a first connection member 144. The first lower pad 142 may be formed of a conductive material on the lower surface of the interconnection layer 120, and may penetrate the passivation layer and be electrically connected to the TSV 130 through, for example, a multi-layered interconnection of the interconnection layer 120. According to some example embodiments, the TSV 130 may be formed to penetrate the interconnection layer 120. In this case, the first lower pad 142 may be directly connected to the TSV 130.

An under bump metal (UBM) may be formed on the first lower pad 142. The first lower pad 142 may be formed of, for example, aluminum (Al) or copper (Cu) and may be formed by using a pulse plating method or a direct current plating method. However, materials of the first lower pad 142 are not limited to the above-stated material, and methods of forming the first lower pad 142 are not limited to the above-stated method.

The first connection member 144 may be formed on the first lower pad 142. The first connection member 144 may be formed of a conductive material, for example, copper (Cu), aluminum (Al), silver (Ag), tin (Sn), gold (Au), or solder. However, materials of the first connection member 144 are not limited thereto. The first connection member 144 may include a multi-layer or a single layer. For example, the first connection member 144 may include a multi-layer that includes, for example, a copper pillar and a solder. The first connection member 144 may include a single-layer formed of, for example, Sn—Ag solder or Cu.

The TSV 130 may penetrate the body 110 so that it may be connected to the first lower pad 142. Although the current example embodiment shows that the TSV 130 has a via-middle structure, the inventive concepts are not limited thereto. For example, the TSV 130 may have a via-first structure or a via-last structure.

In general, TSVs may be classified into three types of structures, i.e., the via-first structure, the via-middle structure, and the via-last structure. The via-first structure refers to a structure in which a TSV is formed before an integrated circuit layer is formed, the via-middle structure refers to a structure in which a TSV is formed after the integrated circuit layer is formed and before an interconnection layer is formed, and the via-last structure refers to a structure in which a TSV is formed after an interconnection layer is formed. In the current embodiment, the TSV 130 has the via-middle structure. Thus, the TSV 130 is formed before the interconnection layer 120 is formed. Due to the via-middle structure, the TSV 130 may be formed to penetrate the body 110 to reach the interconnection layer 120 to be formed later.

The TSV 130 may include at least one metal layer. For example, the TSV 130 may include a barrier metal layer (not shown) and an interconnection metal layer (not shown). The barrier metal layer may include at least one material selected from W, WN, WC, Ti, TiN, Ta, TaN, Ru, Co, Mn, WN, Ni, and NiB, and may be a single layer or a multi-layer. The interconnection metal layer may include, for example. Cu or W. For example, the interconnection metal layer may be formed of Cu, CuSn, CuMg, CuNi, CuZn, CuPd, CuAu, CuRe, CuW, W, or W alloy, but is not limited thereto. For example, the interconnection metal layer may include one or more of Al, Au, Be, Bi, Co, Cu, Hf, In, Mn, Mo, Ni, Pb, Pd, Pt, Rh, Re, Ru, Ta, Te, Ti, W, Zn, and Zr, and may include a stacked structure including one of them or two or more of them. However, materials of the TSV 130 are not limited to the materials specified above. The barrier metal layer and the interconnection metal layer may be formed by using physical vapor deposition (PVD) and chemical vapor deposition (CVD). However, the inventive concepts are not limited thereto.

A spacer insulating layer (not shown) may be interposed between the TSV 130 and the body 110. The spacer insulating layer may prevent the TSV 130 from directly contacting circuit devices in the body 110. The spacer insulating layer may be formed of, for example, oxide, nitride, polymer, or a combination thereof. In some example embodiments, a CVD process may be used to form the spacer insulating layer. The spacer insulating layer may be, for example, an ozone tetra-ethyl-ortho-silicate (O₃ TEOS)-based high aspect ratio process (HARP) oxide layer formed by a sub-atmospheric CVD process. Such a spacer insulating layer may not be formed on the upper surface of the TSV 130.

The upper protection layer 150 protects the first chip 100. The upper protection layer 150 may be, for example, an oxide layer, a nitride layer, or a double layer including an oxide layer and a nitride layer. The upper protection layer 150 may be formed of, for example, oxide, e.g., silicon oxide (SiO₂), by using a HDP-CVD process.

An upper pad 132 may be disposed on the upper protection layer 150. The upper pad 132 may be electrically connected to the TSV 130 penetrating the upper protection layer 150. The upper pad 132 may be formed in the process of forming the TSV 130. The upper pad 132 may not be formed to directly contact the TSV 130, but may be formed to be connected to the TSV 130 through a redistribution line (RDL) (not shown).

A structure of the TSV 130 will be described in more detail with reference to FIG. 16.

When the first chip 100 is formed on the active wafer, the first chip 100 may include, for example, a memory device or a non-memory device. The memory device may include, for example, Dynamic Random-Access Memory (DRAM), Static Random-Access Memory (SRAM), flash memory, Electrically Erasable Programmable Read-Only Memory (EEPROM), Phase-change Random-Access Memory (PRAM), Magnetoresistive Random-Access Memory (MRAM), or Resistive Random-Access Memory (RRAM). The non-memory device may be, for example, a logic device, for example, a microprocessor, a digital signal processor, or a microcontroller, or a device that is similar thereto.

The second chip 200 may include a body 210, an interconnection layer 220, and a chip connection member 240. The body 210 and the interconnection layer 220 are similar to the body 110 and the interconnection layer 120, described above with respect to the first chip 100. Accordingly, descriptions thereof are omitted. The body 210 of the second chip 200 may be formed based on the active wafer instead of the interposer substrate.

The body 210 of the second chip 200 may be thicker than the body 110 of the first chip 100. Accordingly, the thickness of the second chip 200 may be larger than that of the first chip 100. In detail, the first chip 100 may have a first thickness D1, and the first thickness D1 may be, for example, equal to or less than about 100 μm or equal to or less than about 60 μm. The second chip 200 may have a second thickness D2, and the second thickness D2 may be, for example, from about 80 μm to about 300 μm. As another example, the second thickness D2 of the second chip 200 may be a thickness of about 120% to about 300% of the first thickness D1 of the first chip 100. Because the second chip 200 is formed to be thicker than the first chip 100, the gap fill portion 400 may be minimized or prevented from being formed on the upper surface of the second chip 200. Detailed descriptions of the gap fill portion 400 are provided below.

The thickness of the body 210 of the second chip 200 may be adjusted by using a grinding process for a wafer including the second chip 200.

As shown in FIG. 1, unlike the first chip 100, a TSV may not be formed in the body 210 of the second chip 200. However, a TSV may be formed in the second chip 200 if desired.

The chip connection member 240 may include a second lower pad 242 and a second connection member 244. The second lower pad 242 may be formed of a conductive material on the lower surface of the interconnection layer 220, and may penetrate a passivation layer (not shown) and be electrically connected to an integrated circuit layer (not shown) in the body 210 through, for example, a multi-layered interconnection of the interconnection layer 220. Materials of the second lower pad 242 and a methods of forming the second lower pad 242 may be the same as those described above with respect to the first lower pad 142 of the first chip 100.

The second connection member 244 may be formed on the second lower pad 242. Materials of the second connection member 244 and methods of forming the second connection member 244 also may be the same as those described above with respect to the first connection member 144 of the first chip 100. The second connection member 244 may be formed to have a smaller size than the first connection member 144. The interval between second connection members 244 may be formed to be smaller than that between first connection members 144. According to some example embodiments, the size of and the interval between the second connection members 244 may be substantially the same as the size of and the interval between the first connection members 144.

As the second connection member 244 is coupled to the upper pad 132 of the first chip 100, integrated devices in the second chip 200 may be electrically connected to an external connection member 340 of the substrate 300 through the TSV 130 of the first chip 100. Because the second connection member 244 is coupled to the upper pad 132 of the first chip 100 in this manner, the disposition position of the second connection member 244 may be determined according to the disposition position of the TSV 130 of the first chip 100. However, when the upper pad 132 is not directly disposed on the TSV 130, but is disposed in any other portion through a redistribution line, the second connection member 244 may be disposed differently from the TSV 130.

The second chip 200 may be a memory device or a non-memory device. As described above, the memory device may include, for example, DRAM. SRAM, flash memory, EEPROM, PRAM, MRAM, or RRAM. The non-memory device may be a logic device, for example, a microprocessor, a digital signal processor, or a microcontroller.

Both the first chip 100 and the second chip 200 may be, for example, a memory device or a non-memory device. For example, one of the first and second chips 100 and 200 may be a memory device, and the other of the first and second chips 100 and 200 may be a non-memory device. For example, the first chip 100 may be a logic device, and the second chip 200 may be a memory device. Further, as illustrated in FIG. 1, a size (e.g., a footprint) of the first chip 100 may be larger than that of the second chip 200 because the first chip 100 is mounted on the substrate 300 having a relatively large size. For example, by increasing the size of the first chip 100 so that the substrate connection members 140 may be enlarged and may be arranged at relatively large intervals, a mounting process for the first chip 100 on the substrate 300 may be easily performed. However, the size of the first chip 100 may be formed to be substantially the same as that of the second chip 200, if desired.

The substrate 300 is a support substrate on which the first chip 100 and the second chip 200 are mounted, and may include a body layer 310, a lower protection layer 320, an upper protection layer 330, and the external connection member 340. The substrate 300 may be, for example, a ceramic substrate, a PCB, a glass substrate, or an interposer substrate. According to some example embodiments, the substrate 300 may be formed of an active wafer. In the current example embodiment, the substrate 300 may be a PCB. e.g., a PCB for exposed molded underfill (e-MUF).

A multi-layered or single-layered interconnection pattern (not shown) may be formed in the body layer 310, and the external connection member 340 and an upper pad 350 may be electrically connected to each other through the multi-layered or single-layered interconnection pattern. The lower protection layer 320 and the upper protection layer 330 may protect the body layer 310, and may be formed of, for example, a solder resist.

The external connection member 340 is an element that is used when mounting the semiconductor package 1000 on an external system substrate or a main board. The external connection member 340 may include an external lower pad 342 and a connection member 344. As illustrated in FIG. 1, the external connection member 340 may be larger than the substrate connection member 140 or the chip connection member 240. Due to the standardization of interconnection lines formed on a system substrate or main board, or due to physical characteristics of the system substrate or main board, it may be difficult to reduce a size of the system substrate or main board as desired. Accordingly, the interval between and the size of the external connection members, which are disposed on the lower surface of a semiconductor package (which will be mounted on the system substrate or main board) may be relatively large.

The external lower pad 342 may penetrate the lower protection layer 320 and thus may be electrically connected to an interconnection pattern in the body layer 310. The external lower pad 342 may be formed of, for example, aluminum (Al), copper (Cu), and may be formed by using a pulse plating method or a direct current plating method. However, materials of the external lower pad 342 are not limited to the above-stated material, and methods of forming the external lower pad 342 are not limited to the above-stated method.

The connection member 344 may be formed of a conductive material, for example, copper (Cu), aluminum (Al), silver (Ag), tin (Sn), gold (Au), or solder. However, materials of the connection member 344 are not limited thereto. The connection member 344 may include a multi-layer or a single layer. For example, when the connection member 344 includes the multi-layer, the connection member 344 may include, for example, a copper pillar and a solder. When the connection member 344 includes the single-layer, the connection member 344 may be formed of, for example, Sn—Ag solder or Cu. In the current example embodiment, the connection member 344 may be a solder ball.

The gap fill portion 400 may fill a space between the first chip 100 and the second chip 200. The gap fill portion 400 may be formed of, for example, a non-conductive adhesive or non-conductive tape having a fluxing effect. The fluxing effect refers to substantially the same effect as that of a general resin-based flux. In detail, a coating film, which covers a metal surface of a soldered body so as to block the air, may reduce a formation of a metal oxide on the metal surface during soldering due to an active component of the coating film. While forming the melted solder to contact the metal surface of the soldered body, the coating film may be pushed out by the melted solder. As a result, a portion of the pushed-out coating film may function as an insulating material between circuit devices. Such a phenomenon is referred to as the fluxing effect of the coating film. For example, the coating film may correspond to the gap fill portion 400 (e.g., the non-conductive adhesive or the non-conductive tape before soldering, the solder may correspond to the second connection member 244, and the metal surface may correspond to the upper pad 132 or the second lower pad 242.

A gap fill material having the fluxing effect may be formed of, for example, thermosetting resin. For example, epoxy resin, phenol resin, polyimide resin, polyurethane resin, melamine resin, and/or urea resin may be selected as a main component of the thermosetting resin. The thermosetting resin may include one selected from the group consisting of the above-stated resins or a mixture of two or more selected from the group.

Further, a resin that is liquid at room temperature may be selected as the thermosetting resin. If a solid resin is adopted, the solid resin may be combined with a resin, which is liquid at room temperature, so as to be used as the thermosetting resin. An organic acid, for example, a dibasic acid having an alkyl group in a side chain may be adopted to improve the fluxing effect. The number of carbon atoms in the dibasic acid may be equal to or greater than six. However, the number of carbon atoms in the dibasic acid is not limited thereto. A low-grade alkyl group having one to five carbon atoms may be adopted as an alkyl group that is used to form the side chain. A single alkyl group or a plurality of alkyl groups may be adopted to form the side chain. If a plurality of alkyl groups is included in an organic molecule, the plurality of alkyl groups may be the same as each other or may be different from each other.

The gap fill material layer, which includes, for example, the non-conductive adhesive or the non-conductive tape, may be formed to cover the chip connection member 240 on the lower surface of the second chip 200 and/or to cover the upper pad 132 on the upper surface of the first chip 100 before a soldering is performed. For example, in the case of using the non-conductive adhesive, the non-conductive adhesive in a liquid state may be coated on a wafer through dispensing. In the case of using the non-conductive tape, the non-conductive tape may be attached on a wafer like a general tape. When the gap fill material layer is the non-conductive tape, it is easy to attach the non-conductive tape to a wafer, but it may be difficult to control an adhesive material at an edge portion when dividing the wafer into chips. When the gap fill material layer 400 is the non-conductive adhesive, it is difficult to perform a coating process because the non-conductive adhesive has to be coated on each of the chips on a wafer, but controlling an adhesive material at an edge portion when dividing the wafer into chips may not be difficult.

A soldering process is a process for stacking the second chip 200 on the first chip 100. According to a soldering process for stacking the second chip 200 on the first chip 100, a fluxing function of the gap fill material layer (e.g., a non-conductive adhesive or non-conductive tape) may be initially activated at a medium temperature, e.g., a temperature of around 150° C. Next, after melting a solder at a relatively high temperature (e.g., a reflow temperature of around 200° C.), a process of applying a mechanical force onto the solder may be performed to press the solder to be bonded to a metal surface (e.g., the second lower pad 242 and/or the upper pad 132).

In the process of applying a mechanical force onto the solder to press the solder, the gap fill material layer may cover an edge portion including the sides of the first and second chips 100 and 200 while the gap fill layer is pushed out. Accordingly, a pressing process is referred to as an overflow process. The overflow process may be performed at once at a desired (or alternatively, predetermined) temperature or may be performed step-by-step at various temperatures. For example, when the overflow process is performed step-by-step at various temperatures, the overflow process may be performed step-by-step, for example, according to glass transition temperature (Tg) characteristics of the gap fill material layer. The overflow process may be performed up to a relatively low temperature, e.g., a temperature of about 120° C.

In the semiconductor package 1000 according to the current embodiment, through the overflow process, the gap fill portion 400 may have a structure in which more than half of the side of the second chip 200 is covered and only a small portion of the side of the first chip 100 is covered. However, structures of the gap fill portion 400 of the semiconductor package 1000 are not limited thereto. Various structures of the gap fill portion 400 will be described with reference to FIGS. 2 to 15 below.

Recently, in order to implement low power, high speed, and high capacity semiconductor package structures including stacked chips having TSVs, the overflow process for the gap fill material layer becomes gradually important to secure the thinning of a semiconductor package and the reliability of the semiconductor package. For example, at least one chip including a TSV may be stacked on a lower substrate such as PCB, and an uppermost chip of stacked chips may not include a TSV. The at least one chip including a TSV may be stacked after being thinned by the depth of the TSV, which electrically connects the at least one chip to upper and lower chips, and the uppermost chip that does not include a TSV may be stacked after being thinned to lower the entire height of the semiconductor package.

A space between the stacked chips may be filled with a gap fill material layer. In this case, the reliability of the semiconductor package may be improved by sufficiently covering an edge portion of at least one of the chips by using an overflow process for the gap fill material layer. Such an overflow process may not cause a problem in the at least one chip including a TSV, but may cause a problem in the uppermost chip that does not include a TSV. For example, when the gap fill material layer flows on the upper surface of the uppermost chip due to the overflow process and thus remains on the upper surface of the uppermost chip, a mold and the gap fill material layer may contact each other in a subsequent molding process for sealing, thereby causing a crack of the uppermost chip.

For example, in the semiconductor package, the chip including a TSV may have a thickness that is equal to or less than 60 μm. The uppermost chip that does not include a TSV may have a thickness that is equal to or less than 60 μm to lower the entire height of the semiconductor package. However, as stated above, when the uppermost chip is excessively thin, the gap fill material layer may flow such that the gap fill material layer flows along and remains on the upper surface of the uppermost chip. Accordingly, a crack problem may occur in the subsequent molding process.

Edge portions of the stacked chips may be covered with the gap fill material layer to secure the reliability of the stacked chips. For example, the edge of each of the stacked chips may be wrapped with the gap fill material layer so that the stacked chips may be coupled together. In this case, even though an external impact or an internal crack progress in a stacking direction of the chips, the progress is mitigated or blocked by the gap fill material layer thereby protecting the stacked chips. Thus, in order to protect the stacked chips, edges of chips, each including a TSV except the uppermost chip, may be sufficiently covered with the gap fill material layer. However, to mitigate or prevent a crack from occurring, the overflow of the gap fill material layer may be desired to be suppressed with respect to the uppermost chip that does not include a TSV. That is, to mitigate or prevent a crack in a subsequent molding process, the gap fill material layer is controlled to prevent the gap fill material from forming on the upper surface of the uppermost chip. In the meantime, to protect the edge of the uppermost chip and also to promote coupling of the uppermost chip and chips under the uppermost chip, the overflow of the gap fill material layer is performed so that the edge and lower side of the uppermost chip may be covered with the gap fill material layer.

A change of a size (e.g., footprint) of the uppermost chip and a change of physical properties of the gap fill layer may be considered as a method of controlling the overflow of the gap fill material around the uppermost chip. It may not be easy to change the size of the uppermost chip because the size of the uppermost chip is directly related to a design change and production cost thereof. Further, the change of the physical properties of the gap fill layer may be a fundamental method of controlling the overflow of the gap fill material, but may need a long development time and/or a complicated control during a stacking process. On the other hand, the change of the thickness of the uppermost chip, i.e., the increase of the thickness of the uppermost chip, is consistent with the direction of the overflow of the gap fill material layer. Thus, the overflow of the gap fill material layer on the upper surface of the uppermost chip may be easily controlled through the increase of the thickness of the uppermost chip.

In the semiconductor package 1000 according to the current example embodiment, when the first thickness D1 of the first chip 100 is equal to or less than about 60 μm and a third thickness D3 that is the height of a gap fill space between the first chip 100 and the second chip 200 is about 10 μm to about 40 μm, the second thickness D2 of the uppermost chip, i.e., the second chip 200, may be about 80 μm to about 300 μm. A desired structure of the gap fill portion 400 of some example embodiments may be formed in the above-stated condition. However, in the semiconductor package 1000, the thicknesses D1 and D2 of the first and second chips 100 and 200 and the height D3 of the gap fill space are not limited thereto. For example, the thicknesses D1 and D2 of the first and second chips 100 and 200 and/or the height D3 of the gap fill space may be determined so that an entire height of the semiconductor package 1000 may be lowered and a crack of the uppermost chip may be suppressed while securing the reliability of the semiconductor package 1000 by protecting the edges of the stacked chips. Further, based on the thicknesses D and D2 of the first and second chips 100 and 200 and/or the height D3 of the gap fill space, a semiconductor package including a gap fill portion, which is configured by using an overflow process, may be implemented.

The sealant 500 may seal the first chip 100, the second chip 200, and the gap fill portion 400 to protect the first chip 100 and the second chip 200 from external physical and chemical damages. The sealant 500 may be formed, for example, an epoxy-based material, a thermoset material, a thermoplastic material, and/or an ultraviolet (UV) curable material. The thermoset material may include, for example, a phenol-type, acid anhydride-type, or amine-type hardening agent and an addition agent of acrylic polymer.

In addition, the sealant 500 may be formed of resin, and may contain a filler. For example, the sealant 500 may be formed of an epoxy-based material containing a silica filler by about 80% of the epoxy-based material. However, components of the silica filler are not limited thereto. For example, a modulus of the sealant 500 may be adjusted by adjusting the components of the silica filler. The modulus may be an elastic modulus. A material having a relatively small modulus may be relatively flexible or relatively soft, and a material having a relatively large modulus may be relatively solid or relatively hard.

The sealant 500 may be formed by using, for example, a molded underfill (MUF) process. Accordingly, a material, which covers the edges of the first and second chips 100 and 200 and the edge of the gap fill portion 400, may be the same as that filling a space between the first chip 100 and the substrate 300. As illustrated in FIG. 1, the sealant 500 may be formed by using an e-MUF process so that the upper surface of the second chip 200 is exposed.

FIGS. 2 through 15 are cross-sectional views of semiconductor packages 100a through 1000n each having a structure that is different from that of the semiconductor package of FIG. 1, according to other example embodiments of the inventive concepts. For convenience of description, the contents described above with reference to FIG. 1 will be briefly described or omitted.

Referring to FIG. 2, in the semiconductor package 1000a, a gap fill portion 400a may not cover a side surface of a first chip 100, differently from the semiconductor package 1000 of FIG. 1. That is, the gap fill portion 400a may cover a portion of a side surface of a second chip 200 and the upper surface of the first chip 100 that protrudes from the side surface of the second chip 200, while filling a space between the first chip 100 and the second chip 200.

As described with reference to FIG. 1, the gap fill portion 400 may be formed to cover the side surface of the first chip 100 in order to protect the first chip 100. As shown in FIG. 2, however, taking into account a glass transition temperature (Tg) and a viscosity of the gap fill material layer, the overflow process of a gap fill material layer may be adjusted such that the side surface of the first chip 100 is not covered. Even when the overflow of the gap fill material is excessively performed to cover the side surface of the first chip, the overflow of the gap fill material layer may not be formed on the upper surface of the second chip 200, and may not cover the side of the first chip 100. For example, this case may correspond to the case where the first chip 100 and the second chip 200 are different kinds of chips and the size of the first chip 100 is relatively much larger than that of the second chip 200.

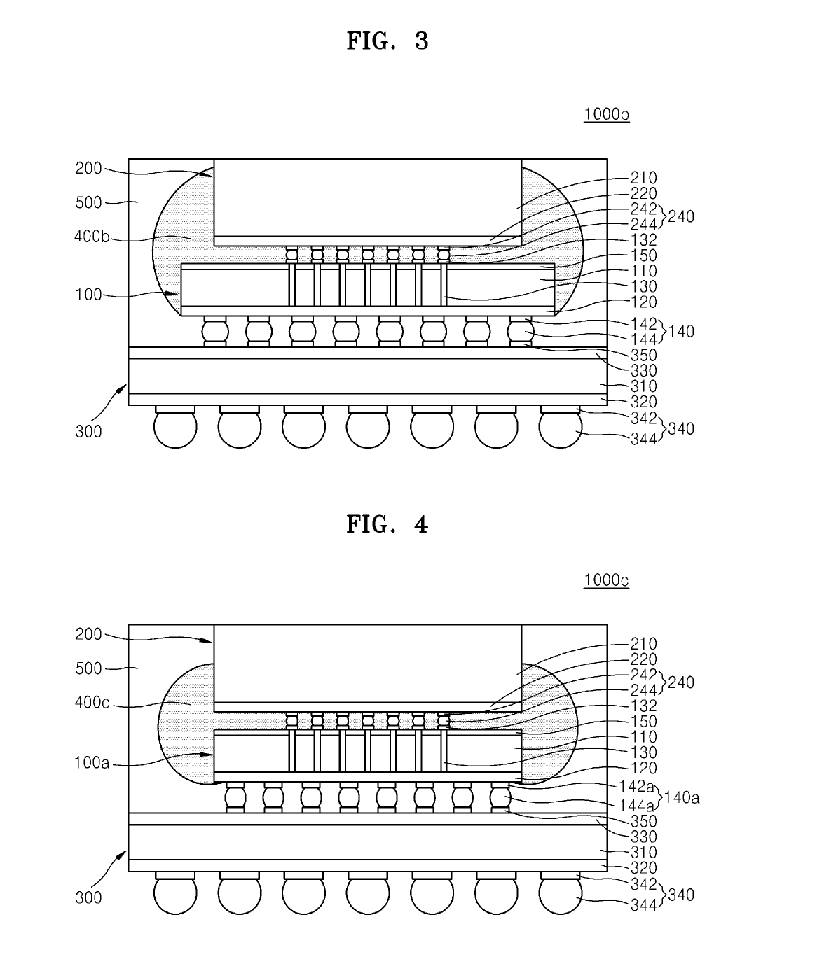

Referring to FIG. 3, in a semiconductor package 1000b, a gap fill portion 400b may cover the entire side of the first chip 100, differently from the semiconductor package 1000 of FIG. 1. Further, the gap fill portion 400b may cover a greater portion of a side surface of the second chip 200. The gap fill portion 400b may not be formed on an upper surface of the uppermost chip, (e.g., the second chip 200) to mitigate or prevent a crack of the second chip 200.

In this manner, a protection for the first and second chips 100 and 200 may be improved as the gap fill portion 400b covers a portion or a greater portion of the side surfaces of the first and the second chips 100 and 200. Accordingly, reliability of the semiconductor package 1000b may be improved.

Referring to FIG. 4, in a semiconductor package 1000c, a size of a first chip 100a may be substantially the same as that of a second chip 200, differently from the semiconductor package 1000 of FIG. 1. Further, the gap fill portion 400c may cover both an entire side surface of the first chip 100a and a portion of the lower surface of the first chip 100a.

Such a structure may be a natural occurrence when considering the direction of the flow of a gap fill material layer during an overflow process. In the semiconductor packages 1000, 1000a, and 1000b of FIGS. 1 through 3, the size of the first chip 100 is larger than that of the second chip 200. Accordingly, a gap fill material layer flowing out from a space between the first chip 100 and the second chip 200 may flow on the side surface of the second chip 200 by using a protruding portion of the upper surface of the first chip 100 as a support base. However, when the size of the first chip 100a and the size of the second chip 200 are substantially the same as each other as shown in the semiconductor package 100c, a gap fill material layer flowing out from a space between the first chip 100 and the second chip 200 may flow much more in the direction of the side surface of the first chip 100 due to gravity.

In the structure of the semiconductor package 1000c, the amount of a gap fill material layer flowing to the side surface of the second chip 200 is relatively small, and thus, the thickness of the second chip 200 may be maintained to be smaller than that of the second chip 200 of the other semiconductor packages. Accordingly, an entire height of the semiconductor package 1000c may be lowered.

As the size of the first chip 100a is reduced, the size of and the interval between substrate connection members 140a that are disposed under the lower surface of the first chip 100a may be reduced. However, the size of the first chip 100a in the semiconductor package 1000c may not be reduced, instead the size of the second chip 200 may be increased to match the size of the first chip 100. In this case, the size of the substrate connection members 140a may be substantially the same as those of the substrate connection members 140 in the semiconductor packages 1000, 1000a, and 1000b of FIGS. 1 through 3.

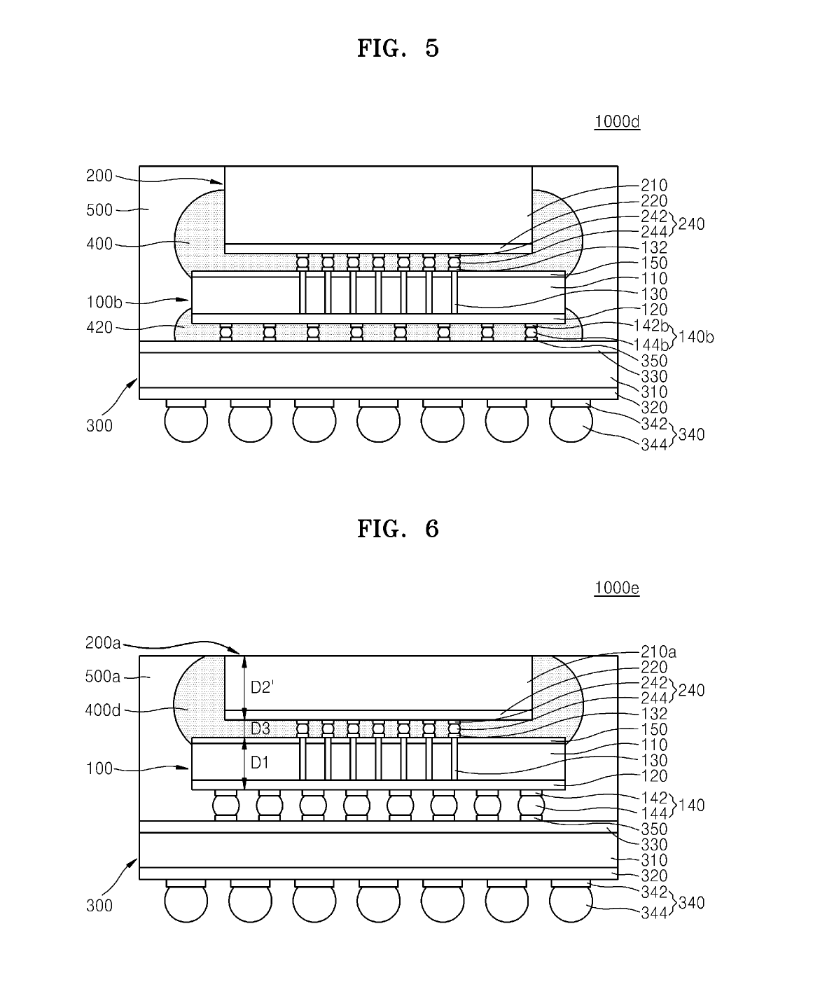

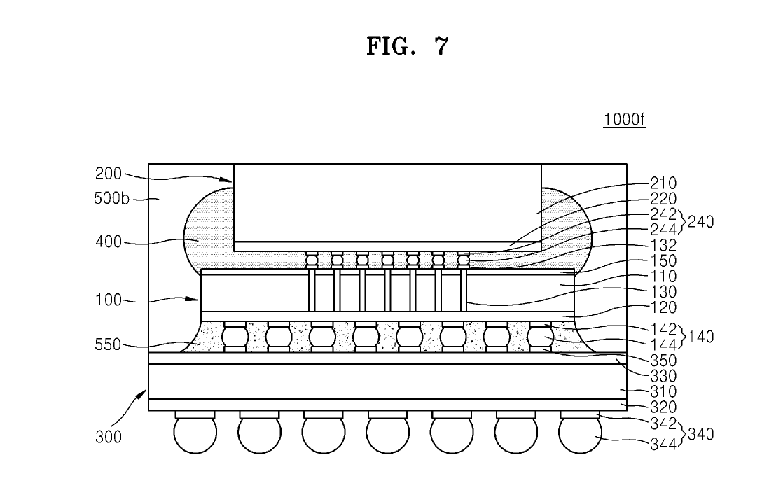

Referring to FIG. 5, in a semiconductor package 1000d, substrate connection members 140b may be formed to have substantially the same size as chip connection members 240. However, a pitch between the substrate connection members 140b may be substantially the same as that between the substrate connection members 140 of the semiconductor package 1000 of FIG. 1.

A space between a first chip 100b and a substrate 300 may be filled with a substrate gap fill portion 420. The substrate gap fill portion 420 may cover a portion of a side surface of the first chip 100b and a portion of an upper surface of the substrate 300. Through an overflow of a gap fill material layer forming the substrate gap fill portion 420, the substrate gap fill portion 420 may be configured to cover the side surface of the first chip 100b and the portion of the upper surface of the substrate 300.

In the semiconductor packages 1000, 1000a, 1000b, and 1000c of FIGS. 1 through 4, the substrate connection members 140 and 140a are formed to be relatively large. Thus, a space between the first chip 100 or 100a and the substrate 300 may be filled with the sealant 500 by using the MUF process. However, in the semiconductor package 1000d, the first chip 100b may be stacked on the substrate 300 and the space between the first chip 100b and the substrate 300 is filled with the substrate gap fill portion 420. In detail, after coating a gap fill material layer on a wafer including the first chip 100b, the overflow of the substrate gap fill material layer may be performed when stacking the first chip 100b on the substrate 300 through soldering. Accordingly, a space between the first chip 100b and the substrate 300 may be filled with the substrate gap fill portion 420, and a portion of the side surface of the first chip 100b and a portion of the upper surface of the substrate 300 may be covered by the substrate gap fill portion 420.

Referring to FIG. 6, in a semiconductor package 1000e, a thickness of a second chip 200a may be smaller than that of the second chip 200 of the semiconductor packages of FIGS. 1 through 5. In the semiconductor package 1000e, the second chip 200a may have a fourth thickness D2′. For example, the fourth thickness D2′ of the second chip 200a may be equal to or less than about 100 μm or equal to or less than about 60 μm, which is similar to the first thickness D1 of the first chip 100.

The semiconductor package 1000e may be implemented by removing an upper portion of the semiconductor package 1000 of FIG. 1 through a grinding process. That is, by removing an upper portion of the second chip 200a and an upper portion of a sealant 500a through the grinding process, the thickness of the second chip 200a may be relatively small and an entire height of the semiconductor package 1000e may be lowered. An upper portion of a body 2100a of the second chip 200a may correspond to a back side of the second chip 200a. Thus, a portion of the back side may be removed through the grinding process without creating substantial issues.

A portion of the gap fill portion 400d may be removed during the grinding process. Thus, a portion of an upper portion of the gap fill portion 400d may be exposed from the sealant 500a. The gap fill portion 400d may not be substantially entirely removed during the grinding process, and in this case, the upper surface of the gap fill portion 400d may remain covered by the sealant 500a.

Referring to FIG. 7, in a semiconductor package 1000f, a space between a first chip 100 and a substrate 3000 may be filled with an underfill 550. The underfill 550 may be formed of an underfill resin (e.g., epoxy resin), and may include, for example, a silica filler and/or flux. The underfill 550 may be formed of a material that is different from that of the sealant 500b formed outside the underfill 550. However, the underfill 550 may be formed of the same material as the sealant 500b.

The space between the first chip 100 and the substrate 300 may be filled with an adhesive member instead of the underfill 550. The adhesive member may be, for example, a non-conductive film (NCF), an anisotropic conductive film (ACF), an UV film, an instant adhesive, a thermoset adhesive, a laser-curing adhesive, an ultrasonic curing adhesive, or a non-conductive paste (NCP).

As the underfill 550 is formed between the first chip 100 and the substrate 300, the sealant 500b may seal the first chip 100, the second chip 200, the gap fill portion 400, and the underfill 550 together. Because the underfill 550 is separately formed, the sealant 500b may be formed through a conventional molding process instead of a MUF process. When the conventional molding process is performed, a grinding process may be performed to reduce the entire height of the semiconductor package 1000f.

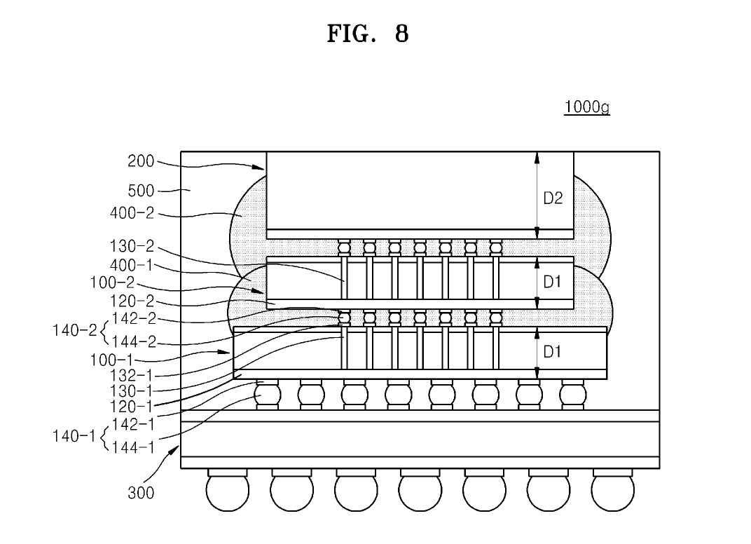

Referring to FIG. 8, a semiconductor package 1000g may include three chips stacked on a substrate 300. That is, in the semiconductor package 1000g, a first-first chip 100-1, a second-first chip 100-2, and a second chip 200 may be sequentially stacked on the substrate 300. The first-first chip 100-1 and the second-first chip 100-2 each may include a TSV, and the second chip 200, which is an uppermost chip, may not include a TSV. As the semiconductor package 1000g includes three chips, the integration density of the semiconductor package 1000g may be improved. Further, when the three chips are memory devices, a memory capacity of the semiconductor package 1000g may be increased.

The first-first chip 100-1 may be substantially the same as the first chip 100 illustrated in FIG. 1. The second-first chip 100-2 is similar to the first chip 100 illustrated in FIG. 1. However, a size of the second-first chip 100-2 may be smaller than that of the first chip 100 illustrated in FIG. 1. Further, a size of and an interval between chip connection members 140-2 that are disposed under the second-first chip 100-2 may be different from a size of and an interval between substrate connection members 140-1. The size of and the interval between the chip connection members 140-2 of the second-first chip 100-2 may be substantially the same as a size of and an interval between chip connection members 240 of the second chip 200. The second-first chip 100-2 may have a first thickness D1 that is the same as that of the first-first chip 100-1.

The size of and the interval between the chip connection members 140-2 of the second-first chip 100-2 may be determined by upper pads 132-1 that are disposed on an upper surface of the first-first chip 100-1. For example, when the size of and the interval between the upper pads 132-1 are relatively large through redistribution lines regardless of the disposition of TSVs 130-1, the size of and the interval between the chip connection members 140-2 may be increased. Although the size of and the interval between the chip connection members 140-2 are increased, each of the chip connection members 140-2 may be electrically connected to a corresponding TSV 130-2 of the second-first chip 100-2 through an interconnection layer 120-2.

A first gap ill portion 400-1 may be disposed between the first-first chip 100-1 and the second-first chip 100-2. The first gap fill portion 400-1 may fill a space between the first-first chip 100-1 and the second-first chip 100-2, and may also cover a portion of a side surface of the first-first chip 100-1 and a substantial portion of a side surface of the second-first chip 100-2. According to some example embodiments, the first gap fill portion 400-1 may cover an entire side surface of at least one of the first-first chip 100-1 and the second-first chip 100-2.

A second gap fill portion 400-2 may be disposed between the second-first chip 100-2 and the second chip 200, and the second gap fill portion 400-2 may be substantially the same as the gap fill portion 400 illustrated in FIG. 1. However, because the first gap fill portion 400-1 covers a portion of the side of the second-first chip 100-2, the second gap fill portion 400-2 may cover both the second-first chip 100-2 and the first gap fill portion 400-1. When the first gap fill portion 400-1 covers an entire side surface of the second-first chip 100-2, the second gap fill portion 400-2 may cover only the first gap fill portion 400-1. The second gap fill portion 400-2 may not cover the upper surface of the second chip 200 while covering the side surface of the second chip 200, like the gap fill portion 400 of FIG. 1. In order to obtain such a structure, the second chip 200 may have a second thickness D2 that is larger than that of the first-first chip 100-1 or second-first chip 100-2.

A sealant 500 may seal the first-first chip 100-1, the second-first chip 100-2, the second chip 200, the first gap fill portion 400-1, and the second gap fill portion 400-2. Also, the sealant 500 may be formed so that the upper surface of the second chip 200 is exposed as illustrated in the semiconductor package 1000 of FIG. 1. That is, the sealant 500 of the semiconductor package 1000g also may be formed by using an e-MUF process.

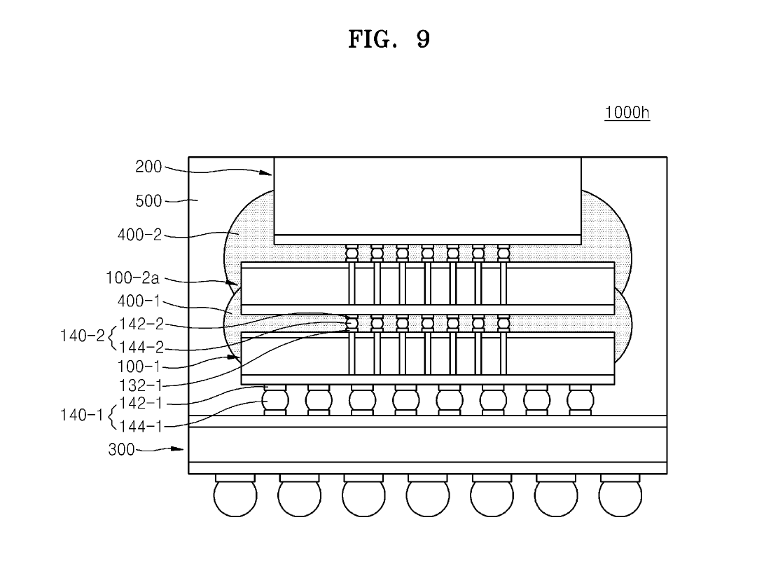

Referring to FIG. 9, a semiconductor package 1000h may be similar to the semiconductor package 1000g of FIG. 8 except a second-first chip 100-2. That is, in the semiconductor package 1000h, a size and a thickness of the second-first chip 100-2a may be the same as those of a first-first chip 100-1. The first-first chip 100-1 may be directly stacked on a substrate 300, whereas the second-first chip 100-2a may be stacked on the first-first chip 100-1. Thus, a size of and an interval between chip connection members 140-2 of the second-first chip 100-2 may be different from a size of and an interval between substrate connection members 140-1 of the first-first chip 100-1. As described above, according to the change of the size and disposition of upper pads 132-1, which is disposed on the upper surface of the first-first chip 100-1, the size of and the interval between the chip connection members 140-2 of the first-second chip 100-2a may be changed.

Like the semiconductor package 1000g of FIG. 8, a first gap fill portion 400-1 may be disposed between the first-first chip 100-1 and the second-first chip 100-2a, and a second gap fill portion 400-2 may be disposed between the second-first chip 100-2a and a second chip 200. According to the change of the size of the second-first chip 100-2a, structures of the first and second gap fill portions 400-1 and 400-2 may be slightly changed. For example, the second gap fill portion 400-2 may cover only a portion of the first gap fill portion 400-1 as illustrated in FIG. 9 or may not cover the first gap fill portion 400-1.

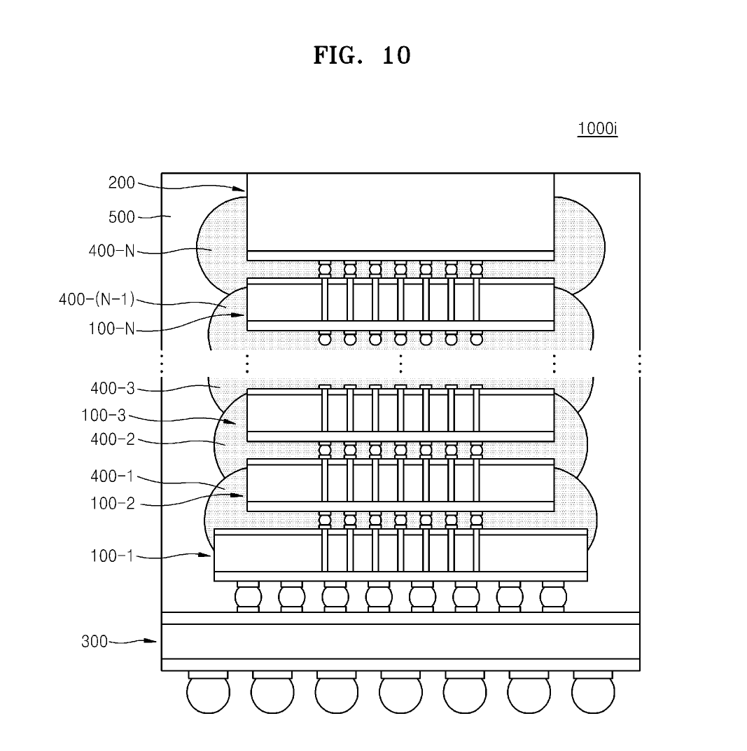

Referring to FIG. 10, a semiconductor package 1000i may include at least four chips on a substrate 300. For example, the semiconductor package 1000i may include a first-first chip 100-1, a second-first chip 100-2, . . . , a Nth-first chip 100-N, and a second chip 200, where N may be a natural number that is equal to or greater than 3.

The first-through Nth-first chips 100-1 through 100-N each may include a TSV. The second chip 200, which is an uppermost chip, may not include a TSV. As illustrated in FIG. 10, thicknesses of the second-through Nth-first chips 100-2 through 100-N may be the same as that of the first-first chip 100-1, and sizes of the second-through Nth-first chips 100-2 through 100-N may be smaller than that of the first-first chip 100-1. For example, the size of the second-through Nth-first chips 100-2 through 100-N may be the same as that of the second chip 200.

A gap fill portion may be disposed between each chip. For example, a first gap fill portion 400-1 may be disposed between the first-first chip 100-1 and the second-first chip 100-2, and a second gap fill portion 400-2 may be disposed between the second-first chip 100-2 and a chip placed immediately thereon. An (N−1)th gap fill portion 400-(N−1) may be disposed between the Nth-first chip 100-N and a chip (not shown) placed immediately thereunder, and an Nth gap fill portion 400-N may be disposed between the Nth-first chip 100-N and the second chip 200.

The first gap fill portion 400-1 may fill a space between the first-first chip 100-1 and the second-first chip 100-2, and may also cover a portion of a side surface of the first-first chip 100-1 and a portion of a side surface of the second-first chip 100-2. The second gap fill portion 400-2 may fill a space between the second-first chip 100-2 and the chip placed immediately thereon, and may cover a portion of the side surface of the second-first chip 100-2, a portion of a side surface of the chip placed immediately thereon, and a portion of the first gap fill portion 400-1. Further, each gap fill portion between an immediately neighboring pair of chips placed on the first-first chip 100-1 may fill a space between the corresponding pair of chips, and may also cover a portion of a side surface of each of the corresponding pair of chips and a portion of another gap fill material layer, which is previously formed under the gap fill portion. Similar to the second gap fill material layer 400-2 of FIG. 8, the Nth gap fill portion 400-N may fill a space between the Nth-first chip 100-N and the second chip 200, and may cover a portion of a side surface of the Nth-first chip 100-N, a portion of the (N−1)th gap fill portion 400-(N−1), and a portion of the side surface of the second chip 200.

As a result, edge portions (i.e., the side surfaces) of all chips between the first-first chip 100-1 and the second chip 200 may be covered and wrapped by the first through Nth gap fill portions 400-1 through 400-N. According to some example embodiments, the side surface of the first-first chip 100-1 and the side surface of the second chip 200 may also be covered by corresponding gap fill portions. For example, the entire side surface of the first-first chip 100-1 may be covered with the first gap fill portion 400-1 by forming the first gap fill portion through an excessive overflow. The entire side surface of the second chip 200 may be covered with the Nth gap fill portion 400-N by removing an upper portion of the semiconductor package 1000i, as illustrated in the semiconductor package 1000e of FIG. 6.

Although only the third gap fill portion 400-3 is illustrated on the upper surface of the third-first chip 100-3 for convenience, an upper pad of the third-first chip 100-3 and a chip connection member of a chip placed on the third-first chip 100-3 may be connected to each other in the third gap fill portion 400-3. Further, the same concept also may be applied to the lower surface of the Nth-first chip 100-N.

The size and disposition of chip connection members of each chip are not limited to the structure illustrated in FIG. 10, and may be adjusted according to a method that is similar to the method described with reference to FIG. 8. A scaling 500 may seal all chips stacked on the substrate 300 and the gap fill portions between the chips. Also, the sealant 500 may be formed through an e-MUF process so that the upper surface of the second chip 200 can be exposed as illustrated in the semiconductor package 1000 of FIG. 1.

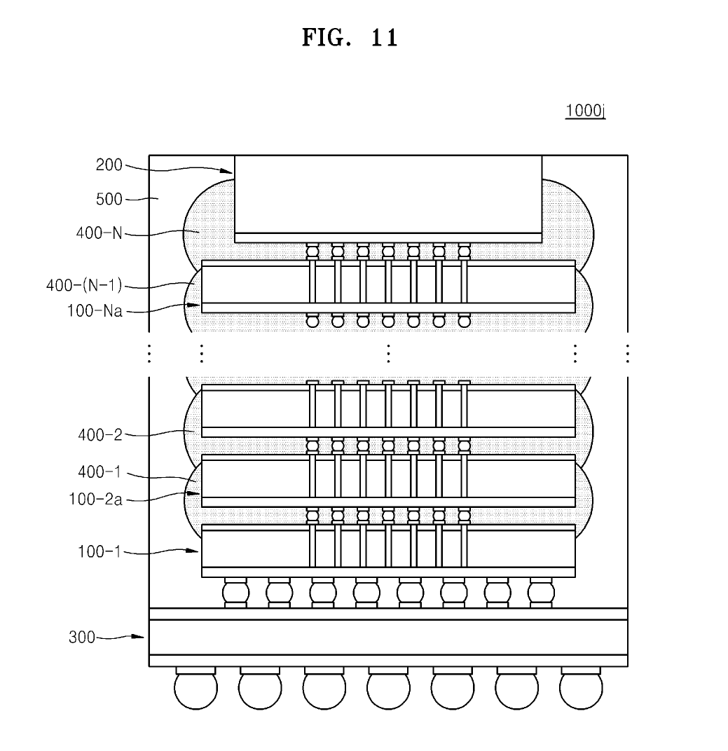

Referring to FIG. 11, a semiconductor package 1000j may be substantially the same as the semiconductor package 1000i of FIG. 10, except that sizes of a second-first chip 100-2a through a Nth-first chip 100-Na are the same as that of the first-first chip 100-1. However, in the semiconductor package 1000j, similar to the semiconductor package 1000h of FIG. 9, an Nth gap fill portion 400-N may cover only a portion of an (N−1)th gap fill portion 400-N−1) or may not cover the (N−1)th gap fill portion 400-(N−1).

The size and/or disposition of chip connection members of each chip of the semiconductor package 1000j are not limited to the structure illustrated in FIG. 11, and may be adjusted according to methods that is similar to the method described with reference to FIG. 9.

Referring to FIG. 12, a semiconductor package 1000k may include a first chip 100, a second chip 200, a gap fill portion 400, and a sealant 500. That is, the semiconductor package 1000k may not include the substrate 300 of the semiconductor package 1000 of FIG. 1. Accordingly, the first chip 100 may function as a support substrate of the semiconductor package 1000k, like the substrate 300 of the semiconductor package 1000 of FIG. 1. A package structure in which a chip is formed on another chip in this manner may be referred to as a chip on chip (COC) package structure.

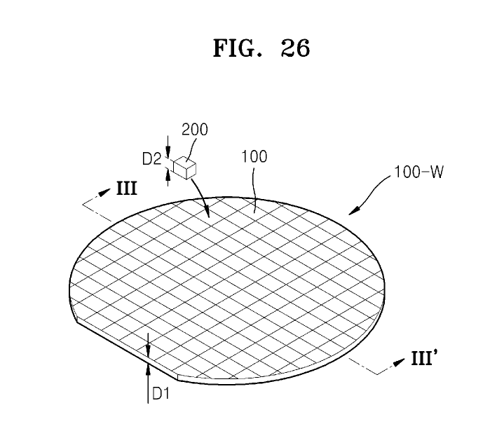

Such a COC package in itself may form a semiconductor package. However, the COC package may also form a semiconductor package of an intermediate step, which is to be mounted on a base substrate such as a PCB. The CoC package may be manufactured through processes illustrated in FIGS. 26 through 29.

Also in the semiconductor package 1000k, the second chip 200 may be formed to be thicker than the first chip 100. Accordingly, a gap fill portion 400 may cover only a portion of a side surface of the second chip 200 and may not exist on an upper surface of the second chip 200.

A sealant 500 may cover a side surface of the first chip 100, the side surface of the second chip 200, and a side surface of the gap fill portion 400. That is, the upper surface of the second chip 200 may be exposed from the sealant 500, and the lower surface of the first chip 100 may also be exposed from the sealant. In the event that the sealant 500 is not formed on the lower surface of the first chip 100, a substrate connection member 140 disposed on the lower surface of the first chip 100 may also be exposed. The lower surface of the sealant 500 may form the same plane as the lower surface of the first chip 100.

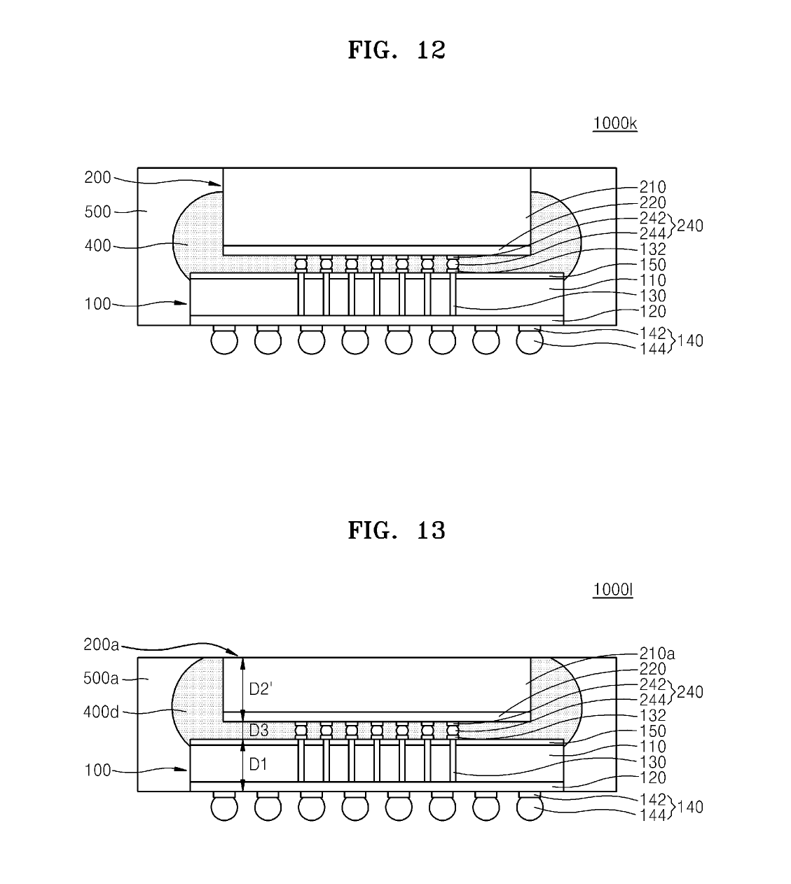

Referring to FIG. 13, a semiconductor package 10001 may be substantially the same as the semiconductor package 1000k of FIG. 12 except the thickness of a second chip 200a. In the semiconductor package 10001, a thickness of the second chip 200a may be smaller than that of the second chip 200 of the semiconductor package 1000k of FIG. 12. The second chip 200a of the semiconductor package 10001 may have the fourth thickness D2′, like the second chip 200a of the semiconductor package 1000e of FIG. 6.

The semiconductor package 10001 may be implemented by removing an upper portion of the semiconductor package 1000e of FIG. 12 through a grinding process. That is, by removing an upper portion of the second chip 200a and an upper portion of a sealant 500a through the grinding process, the thickness of the second chip 200a may become thinner, thereby lowing an entire height of the semiconductor package 10001.

A portion of a gap fill portion 400d may be removed during the grinding process, and thus, a portion of an upper portion of the gap fill portion 400d may be exposed from the sealant 500a. The gap fill portion 400d remaining after performing the grinding process may be covered by the sealant 500a.

Referring to FIG. 14, a semiconductor package 1000m is similar to the semiconductor package 1000 of FIG. 1, but a structure of a sealant of the semiconductor package 1000m may be different from that of the semiconductor package 1000 of FIG. 1.

That is, the semiconductor package 1000m may include an internal sealant 500in, which seals a first chip 100, a second chip 200, and a gap fill portion 400, and an external sealant 500out which is formed on a substrate 300 and seals the internal sealant 500in.

The internal sealant 500in and the external sealant 500out may be formed of a same material or different materials. In addition, a modulus of the internal sealant 500in and a modulus of the external sealant 500out may be the same as each other or different from each other. When the modulus of the internal sealant 500in and the modulus of the external sealant 500out are different from each other, the modulus of the internal sealant 500in may be lower than that of the external modulus 500out. For example, the internal sealant 500in may have a relatively low modulus because the internal sealant 500in is formed on a wafer and processes have to be performed in a state where the internal sealant 500in was formed. The external sealant 500out may have a relatively high modulus because the external sealant 500out is formed at the almost last step of a semiconductor package process and a main function of the external sealant 500out is to protect internal semiconductor chips.

The internal sealant 500in may be formed through a general molding process because a substrate connection member 140 is not sealed by the internal sealant 500in. If necessary, the upper surface of the second chip 200 may be exposed through a grinding process. The external sealant 500out may be formed by using an MUF process. However, processes of forming the external sealant 500out are not limited to the MUF process.

The semiconductor package 1000 of FIG. 1 may be formed by stacking the first chip on the substrate 300, stacking the second chip 200 on the first chip 100, and then sealing the first and second chips 100 and 200. However, the semiconductor package 1000m may be formed by forming an internal semiconductor package such as the COC package of FIG. 12, stacking the internal semiconductor package on the substrate 300 such as a PCB, and then sealing the internal semiconductor package.

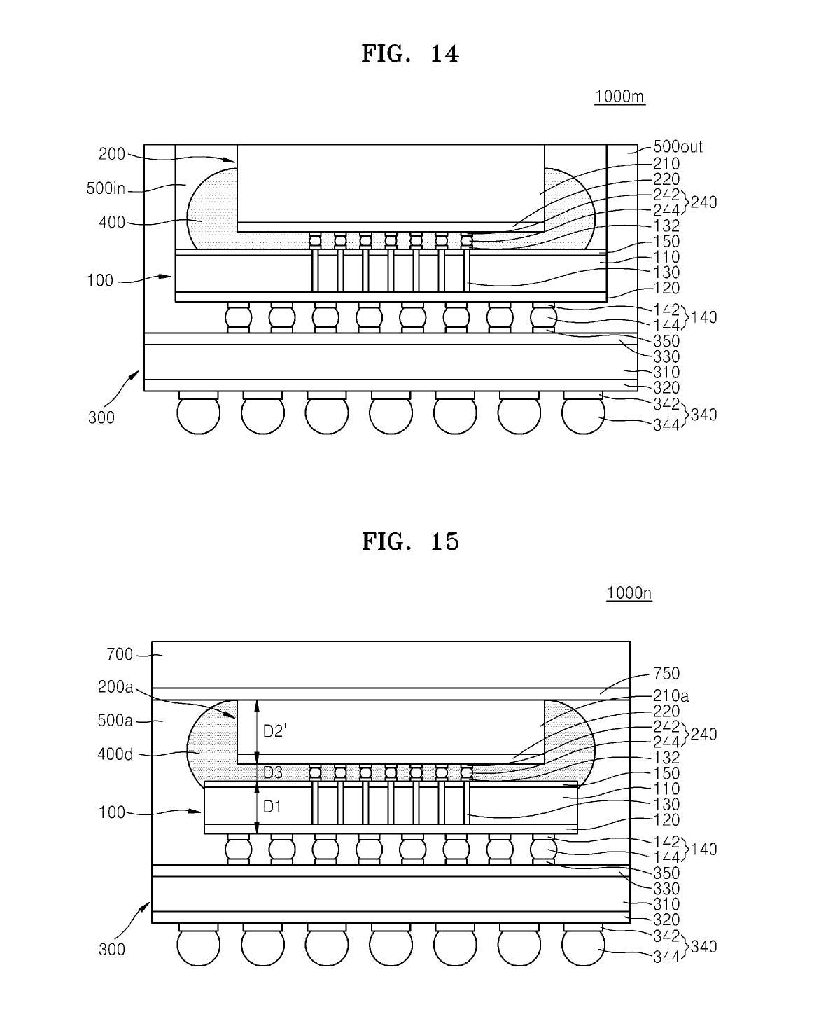

Referring to FIG. 15, a semiconductor package 1000n may further include a thermal interface material (TIM) 750 and a heat sink 700, compared to the semiconductor package 1000e of FIG. 6.

The TIM 750 has a relatively high heat conductivity, and may be formed of a material that may attach the heat sink 700 to a second chip 200a and a sealant 500a. The heat sink 700 may have a structure for easily discharging heat generated by a first chip 100 and/or the second chip 200a. The heat sink 700 may be formed of a metal material having a relatively high heat conductivity to easily discharge the heat.

Although the semiconductor package 1000n has a structure in which the TIM 750 and the heat sink 700 are disposed on the semiconductor package 1000e of FIG. 6, structures of the semiconductor package 1000n are not limited thereto. For example, the TIM 750 and the heat sink 700 may be disposed on any one of the semiconductor packages illustrated in FIGS. 1 through 5 and 7 through 14.

FIG. 16 is a cross-sectional view showing in more detail a chip including a TSV, which is used for the semiconductor packages of FIGS. 1 through 15.

Referring to FIG. 16, a semiconductor chip, e.g., a first chip 100, may include a body 110, an interconnection layer 120, a TSV 130, an external connection member 140, and an upper protection layer 150. An inverted structure of the first chip 100 may correspond to the first chip 100 of the semiconductor package 1000 of FIG. 1.

The body 110 may include a semiconductor substrate 102, an interlayer insulating layer 104, and an integrated circuit layer 105. The semiconductor substrate 102 may be a semiconductor wafer, may include a group IV material, or may include a group III-V material. Various wafers (e.g., a single-crystalline wafer, an epitaxial wafer, a polished wafer, an annealed wafer, or an SOI wafer) may be used as the semiconductor substrate 102.

The semiconductor substrate 102 may include a first surface F0 and a second surface F2, and the integrated circuit layer 105. For convenience of understanding, FIG. 16 illustrates that the integrated circuit layer 105 is formed on the first surface F0 In such case, an impurity doping area (not shown) included in the integrated circuit layer 105 may be formed in an upper area adjacent to the first surface F0 of the semiconductor substrate 102. A lower area of the semiconductor substrate 102, which is adjacent to the second surface F2, may be a lightly doped area or an undoped area.

The interlayer insulating layer 104 may be formed on the first surface F0 of the semiconductor substrate 102 while covering the integrated circuit layer 105. The interlayer insulating layer 104 may separate circuit devices in the integrated circuit layer 105 from each other. Also, the interlayer insulating layer 104 may separate the circuit devices in the integrated circuit layer 105 from the interconnection layer 120. The interlayer insulating layer 104 may include one selected from an oxide layer, a nitride layer, a low dielectric constant layer, and a high dielectric constant layer or a stacked structure including two or more of them.

The integrated circuit layer 105 may be formed adjacent to the first surface F0 of the semiconductor substrate 102 in the semiconductor substrate 102 and the interlayer insulating layer 104, and may include a plurality of circuit devices. The integrated circuit layer 105 may include, for example, a plurality of transistors, a plurality of diodes, and/or a plurality of capacitors, depending on a type of the first chip 100. The first chip 100 may be a memory device or a non-memory device, depending on a structure of the integrated circuit layer 105. In the case where the first chip 100 is a non-memory device, the first chip 100 may be a logic device, for example, a central processing unit (CPU) or a microprocessor. In the case where the first chip 100 is a memory device, the first chip 100 may include any one of various memory devices, for example, DRAM, SRAM, flash memory, EEPROM, PRAM, RRAM, Ferroelectric Random-Access Memory (FeRAM), or MRAM. A conductive contact 107 may electrically connect the circuit devices of the integrated circuit layer 105 to an interconnection pattern of the interconnection layer 120.

As the interlayer insulating layer 104 constitutes a portion of the body 110. Thus, the upper surface of the interlayer insulating layer 104 may correspond to a front side F1 of the body 110. Further, the second surface F2 of the semiconductor substrate 102 may correspond to a back side F2 of the body 110.

The interconnection layer 120 may include an intermetallic insulating layer 122, interconnection lines 124, and vertical contacts 126. The intermetallic insulating layer 122 may be provided on the interlayer insulating layer 104 so as to cover the interconnection lines 124 that are multi-layer interconnection lines. The intermetallic insulating layer 122 may separate the interconnection lines 124 from each other. Although the intermetallic insulating layer 122 illustrated in FIG. 16 is a single layer, the intermetallic insulating layer 122 may include a plurality of insulating layers. For example, the intermetallic insulating layer 122 may include a plurality of insulating layers, depending on the number of layers of the interconnection lines 134.

The interconnection lines 124 may be formed in the intermetallic insulating layer 122 on the interlayer insulating layer 104, and may be electrically connected to a TSV 130. The interconnection lines 124 may be formed to have more than one layers, and different interconnection lines corresponding to different layers may be electrically connected to each other via the vertical contacts 126. The interconnection lines 124 may be used to connect the circuit devices of the integrated circuit layer 105 to each other to form a desired (or alternatively, predetermined) circuit or may be used to electrically connect the circuit devices to an external device.

In the current example embodiment, the interconnection lines 124 may include three interconnection lines, e.g., a first interconnection line 124-1 as a lowest layer, a second interconnection line 124-2 as an intermediate layer, and a third interconnection line 124-3 as a highest layer. A first vertical contact 126-1 may be disposed between the first interconnection line 124-1 and the second interconnection line 124-2, a second vertical contact 126-2 may be disposed between the second interconnection line 124-2 and the third interconnection line 124-3. Thus, different interconnection lines corresponding to different layers may be connected to each other by the first and second vertical contacts 126-1 and 126-2. Pads (not shown), which are connected to the external connection member 140, may be disposed on the third interconnection line 124-3. The interconnection lines 124 may be formed of, for example, Cu and/or Al. For example, the first and second interconnection lines 124-1 and 124-2 may be formed of Cu, and the third interconnection line 124-3 may be formed of Al.

Although the structure and material of the interconnection lines 124 formed of three layers are described above, the inventive concepts are not limited thereto. For example, the interconnection lines 124 may be formed of four or more layers or two or less layers. The interconnection lines 124 are not limited to Cu or Al, and may be formed of a different metal, for example, W, Ni, Au, or Ag. Further, the connection structure of the interconnection lines 124 illustrated in FIG. 16 is merely an example. Connection structures of the interconnection lines 124 are not limited to the structure illustrated in FIG. 16, and may be variously changed depending on a type of the semiconductor chip 100.

The first through third interconnection lines 124-1, 124-2, and 124-3 of the interconnection lines 124 and the first and second vertical contacts 126-1 and 126-2 may be formed of a same material or may also be formed of different materials. For example, in a damascene structure, the interconnection lines 124 and the vertical contacts 126 corresponding thereto may be formed of a same material. Furthermore, the interconnection lines 124 and the vertical contacts 126 may include at least one barrier metal as well as an interconnection metal.

The TSV 130 may penetrate the interlayer insulating layer 104 and the semiconductor substrate 102, and one end of the TSV 130 may be exposed on the second surface F2 of the semiconductor substrate 102. The TSV 130 may have a structure protruding from the second surface F2 of the semiconductor substrate 102, and a side surface of a protruding portion of the TSV 130 may be surrounded by the upper protection layer 150 on the second surface F2 of the semiconductor substrate 102. The upper protection layer 150 may be, for example, an oxide layer, a nitride layer, or a double layer including an oxide layer and a nitride layer. Further, the upper protection layer 150 may be firmed of oxide (e.g., silicon oxide (SiO₂)) by using, for example, a HDP-CVD process.

As illustrated in FIG. 16, an upper pad 132 may be disposed on an exposed side of the TSV 130. According to some example embodiments, a redistribution line (not shown) may be formed on the exposed side of the TSV 130, and the upper pad 132 may be formed on the redistribution line.

The TSV 130 may include an interconnection metal layer 136 and a barrier metal layer 134. The interconnection metal layer 136 may include, for example, Cu or W. For example, the interconnection metal layer 136 may be formed of Cu, CuSn, CuMg, CuNi, CuZn, CuPd, CuAu, CuRe, CuW, W, or W alloy, but is not limited thereto. For example, the interconnection metal layer 136 may include one or more of Al. Au, Be, Bi, Co, Cu, Hf, In, Mn, Mo, Ni, Pb, Pd, Pt, Rh, Re, Ru, Ta, Te, Ti, W, Zn, and Zr, and/or may include a stacked structure including one of them or two or more of them. The barrier metal layer 134 may include at least one material selected from W, WN, WC, Ti, TiN, Ta, TaN, Ru, Co, Mn, WN, Ni, and NiB, and/or may be a single layer or a multi-layer. However, materials of the TSV 130 are not limited to the above-stated materials. The barrier metal layer 134 and the interconnection metal layer 136 may be formed by, for example, a PVD process or a CVD process. However, the inventive concepts are not limited thereto.

A spacer insulating layer 135 may be interposed between the TSV 130 and the semiconductor substrate 102. The spacer insulating layer 135 may block a direct contact between circuit devices in the body 110 and the TSV 130. The spacer insulating layer 135 may be formed of, for example, oxide, nitride, polymer, or a combination thereof. In some example embodiments, a CVD process may be used to form the spacer insulating layer 135. The spacer insulating layer 135 may be, for example, an O₃/TEOS-based HARP oxide layer formed by a sub-atmospheric CVD process. The spacer insulating layer 135 may not be formed on the upper surface of the TSV 130.

A passivation layer 144 may be formed on the interconnection layer 120. The passivation layer 144 may cover the surface of the first chip 100 to protect the first chip 100. The passivation layer 144 may be, for example, an oxide layer, a nitride layer, or a double layer including an oxide layer and a nitride layer. Further, the passivation layer 144 may be formed of oxide, e.g., silicon oxide (SiO₂), by using a HDP-CVD process.

The external connection terminal 140 may be a bump or a solder ball. The external connection member 140 may be connected to the interconnection layer 120, e.g., the third interconnection line 124-3, and thus may be electrically to the TSV 130. The external connection member 140 may correspond to the substrate connection member 140 of the semiconductor package 1000 of FIG. 1. Further, the external connection member 140 may correspond to the chip connection member 140-2 disposed in the first-second chip 100-2 of the semiconductor package of FIG. 8.

The external connection terminal 140 may be formed on the third interconnection line 124-3, and may be formed of, for example, a solder including tin (Sn). According to some example embodiments, the external connection terminal 140 may be formed of Pd, Ni, Ag, Pb, or an alloy thereof. An upper portion of the external connection terminal 140 may have a hemispherical shape. The external connection terminal 140 may have the hemispherical shape through a reflow process, but a shape that is slightly different from the hemispherical shape may be formed according to the reflow process. Although not illustrated, a pad may be disposed between the external connection member 140 and the third interconnection line 124-3. According to some example embodiments, the third interconnection line 124-3 itself may function as the pad. An under bump metal (UBM) (not shown) may be disposed in a lower portion of the external connection member 140.

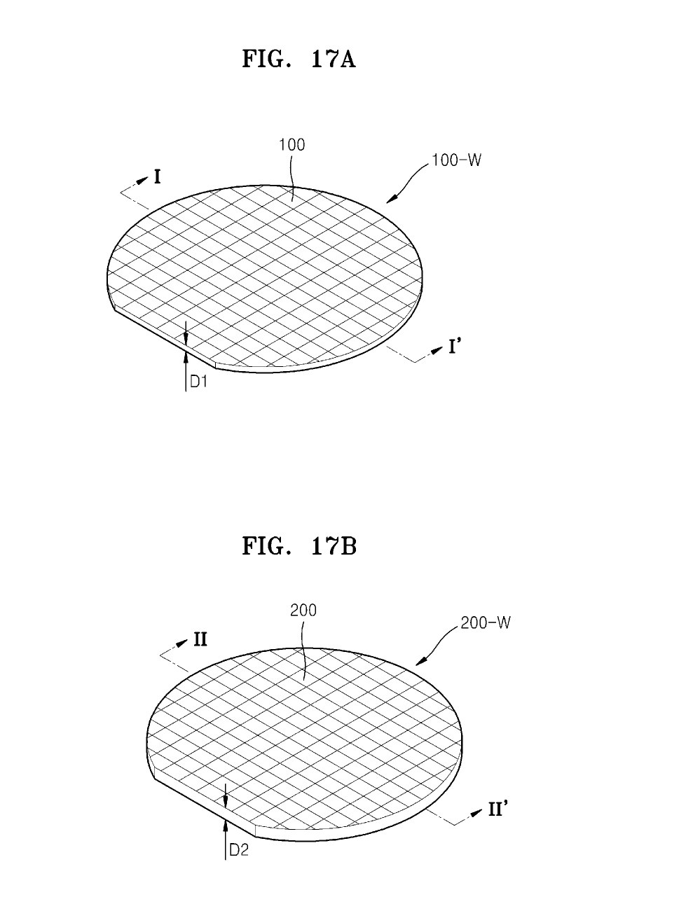

FIG. 17A is a perspective view showing a first wafer 100-W including a plurality of first chips 100, each of which includes a TSV, and FIG. 17B is a perspective view showing a second wafer 200-W including a plurality of uppermost chips 200, each of which does not include a TSV. The first chips 100 and the uppermost chips 200 may respectively correspond to the first and second chips used in the semiconductor packages of FIGS. 1 through 16.

That is, the first wafer 100-W of FIG. 17A may be a wafer that includes a plurality of first chips 100 corresponding to the above-described first chip 100 which includes a TSV. Accordingly, the first wafer 100-W may have the first thickness D1 that is equal to the thickness of the above-described first chip 100. On the other hand, the second wafer 200-W of FIG. 17B may be a wafer that includes a plurality of second chips 200 corresponding to the above-described second chip 200 which does not include a TSV. Accordingly, the second wafer 200-W may have the second thickness D2 that is equal to the thickness of the above-described second chip 200.

The first wafer 100-W may be divided into the plurality of first chips 100 through a sawing process. The second wafer 200-W may be divided into the plurality of second chips 200 through a sawing process. Each individual first chip 100 and each individual second chip 200 may be stacked on the substrate 300 to form the semiconductor packages of FIGS. 1 through 13. When the above-described first chip 100 is larger than the above-described second chip 200 like in the semiconductor package 1000 of FIG. 1, the first chips 100 of the first wafer 100-W may be formed to have a size (e.g., footprint) that is larger than that of the second chips 200 of the second wafer 200-W. For example, the first chips 100 of the first wafer 100-W and the second chips 200 of the second wafer 200-W may be formed to have a same size, and the second chips 200 may be made smaller than the first chips 100 by using a sawing process.

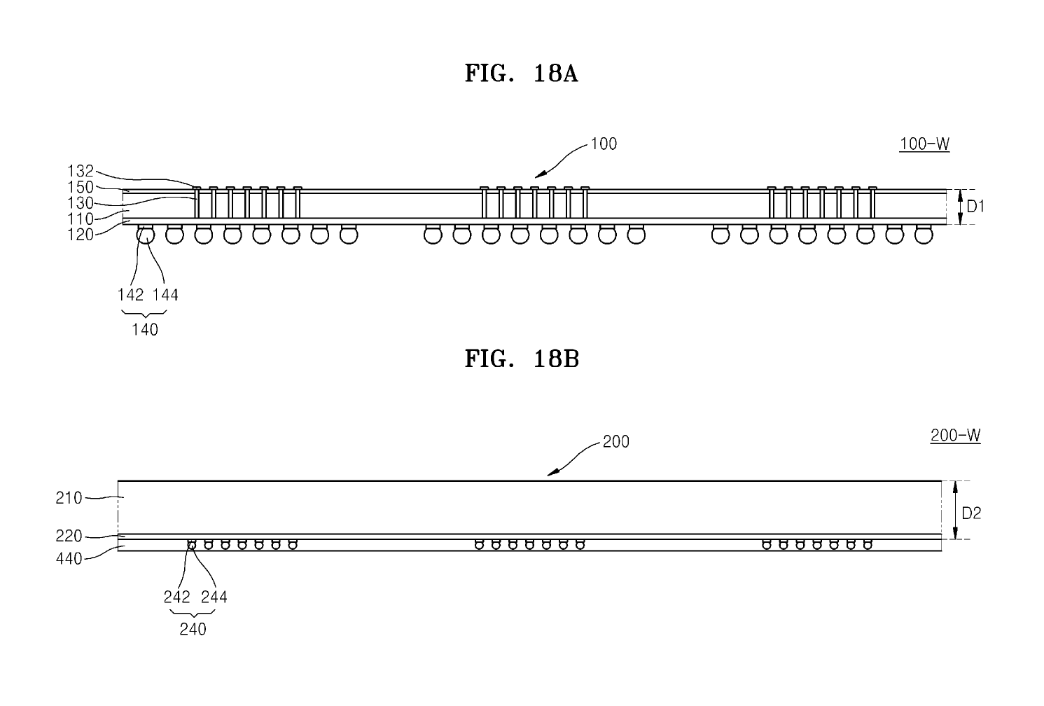

FIG. 18A is a cross-sectional view taken along a line I-I′ of FIG. 17A, and FIG. 18B is a cross-sectional view taken along a line II-II′ of FIG. 17B.

Referring to FIG. 18A, the first wafer 100-W includes the plurality of first chips 100 each including a plurality of TSVs 130. Further, as described in the semiconductor package of FIG. 1, a substrate connection member 140 is disposed on a lower surface of each first chip 100, an upper pad 132 is disposed on an upper surface of each first chip 100, and the substrate connection member 140 and the upper pad 132 may be electrically connected to each other through a TSV 130 and an internal interconnection line (not shown).

Referring to FIG. 18B, the second wafer 200-W includes the plurality of second chips 200, and a TSV may not be formed in the plurality of second chips 200. A chip connection member 240 disposed on a lower surface of each second chip 200 may be electrically connected to integrated circuits (not shown) in a body 210 through an internal interconnection line (not shown) of an interconnection layer 220. A gap fill material layer 440 may be coated on the lower surface of the second wafer 200-W. The gap fill material layer 440 may be formed of, for example, a nonconductive adhesive or nonconductive tape having a fluxing effect as described above.

The first wafer 100-W may have a first thickness D1, and the second wafer 200-W may have a second thickness D2. The second thickness D2 of the second wafer 200-W may be larger than the first thickness D1 of the first wafer 100-W. For example, the first thickness D1 may be equal to or less than about 100 μm or equal to or less than about 60 μm. The second thickness D2 may be about 80 μm to about 300 μm. For example, the second thickness D2 may be a thickness of about 120% to about 300% of the first thickness D1.

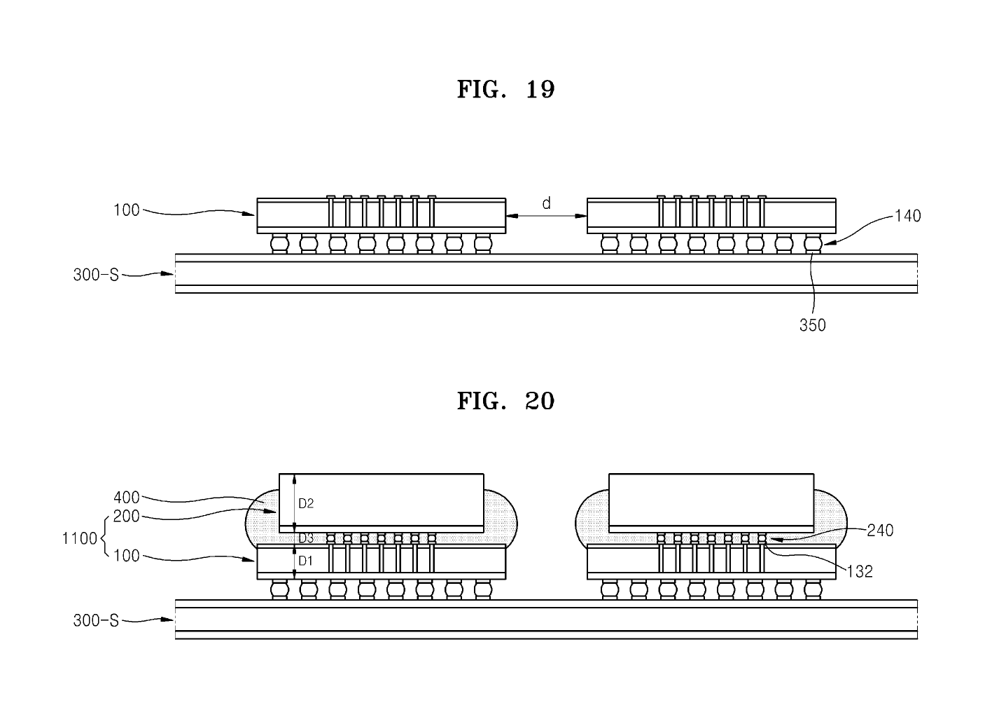

FIGS. 19 through 22 are cross-sectional views showing a method of manufacturing the semiconductor package of FIG. 1, according to an example embodiment of the inventive concepts.

Referring to FIG. 19, first chips 100 are stacked at a first interval d on a strip substrate 300-S, which has a rectangular shape and is elongated in a direction. Substrate connection members 140 of each of the first chips 100 may be coupled to corresponding upper pads 350 disposed on the strip substrate 300-S, through a soldering process.

An adhesive gap fill material layer, (e.g., a nonconductive adhesive or a nonconductive tape) may be omitted in the soldering process. However, a gap fill material layer may be formed if necessary. The gap fill material layer may be coated on the first wafer 100-W of FIG. 17A before the first wafer 100-W is divided into the plurality of first chips 100. According to some example embodiments, the gap fill material layer may be coated on the strip substrate 300-S. Instead of the gap fill material, an NCF, an ACF, an UV film, an instant adhesive, a thermoset adhesive, a laser-curing adhesive, an ultrasonic curing adhesive, an NCP, or the like may be used as a general adhesive member.

The first interval d between the first chips 100 may be appropriately determined in consideration of the size of a semiconductor package to be finally formed. Further, the first interval d may be determined in consideration of the form of a gap fill material layer protruding due to the overflow of a gap fill material layer when stacking the second chip 200 and also in consideration of a width of sawing when dividing the first chips 100 after a molding process to form semiconductor packages.

When the first interval d is maintained to be sufficiently wide, it is possible to prevent a side surface of the first chip 100 and a side surface of the second chip 200 from being exposed to an outside, after completion of a semiconductor package. Accordingly, physical damages due to contamination, damages, and/or interfacial desquamation, which occur when a silicon of the side surfaces of the first and second chips 100 and 200 are exposed to the outside, may be mitigated or prevented. As a result, reliability of the semiconductor package may be improved.

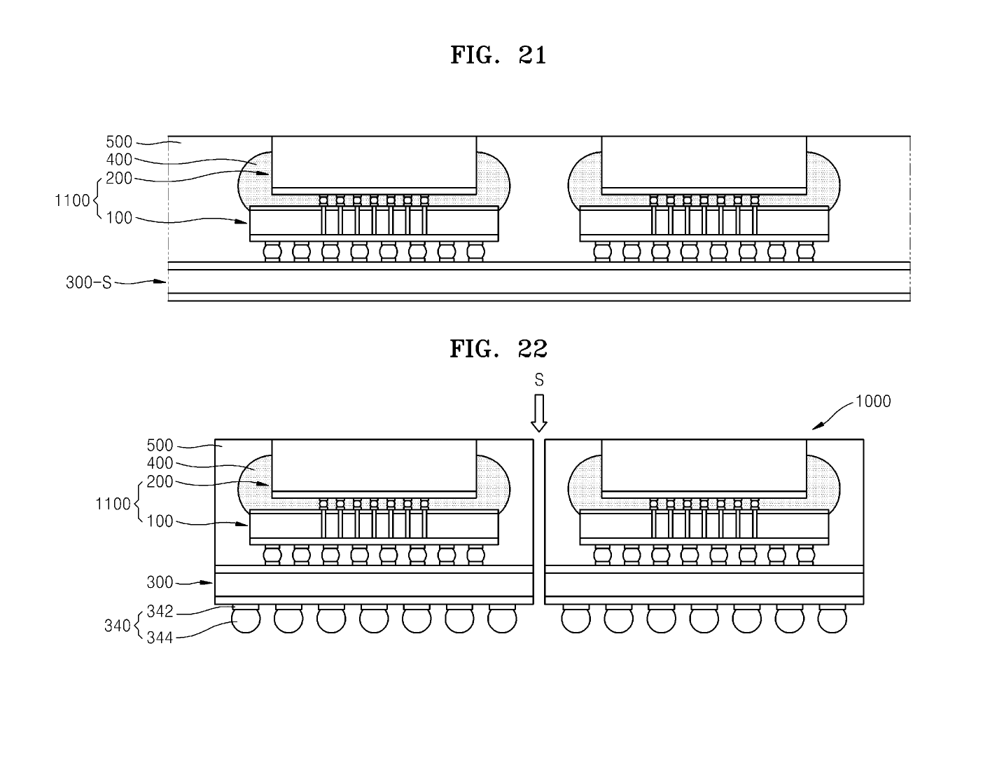

Referring to FIG. 20, second chips 200 are stacked on the first chips 100. Similar to the stacking of the first chips 100, chip connection members 240 of each of the second chips 200 may be coupled to corresponding upper pads 132 disposed on each of the first chips 100, through a soldering process. In a process of stacking the second chips 200, a height of a gap fill space between the first chip 100 and the second chip 200 may be formed to have a third thickness D3. For example, the third thickness D3 may be from about 10 μm to about 40 μm.

In a soldering process for stacking the second chips 200, an overflow process may be performed with respect to a gap fill material layer (refer to 440 of FIG. 18B) disposed on a lower surface of each of the second chips 200. The gap fill material layer 440 may be formed of, for example, a non-conductive adhesive or non-conductive tape having a fluxing effect, and may be coated on the second wafer 200-W before the second wafer 200-W is divided into the second chips 200. A gap fill portion 400 having a form as illustrated in FIG. 20 may be formed by the overflow of the gap fill material layer 440.

The gap fill portion 400 may fill a space between the first chip 100 and the second chip 200, and may cover edge portions of side surfaces of the first and second chips 100 and 200. Depending on the extent of the overflow of the gap fill material layer 440, the gap fill portion 400 may not cover the side of the first chip 100 as shown in FIG. 2 or may cover almost all of the side of the first chip 100 as shown in FIG. 3. However, because the second chip 200 is relatively thicker than the first chip 100, the gap fill portion 400 may not exist on the upper surface of the second chip 200, because the gap fill portion 400 does not exist on the upper surface of the second chip 200, a crack of the second chip 200 may be mitigated or prevented from occurring in a molding process, for example, a subsequent e-MUF process.

For example, if the gap fill portion 400 is formed so as not to exist on the upper surface of the second chip 200, the gap fill portion 400 may be formed to cover substantially the entire side surface of the first chip 100 and substantially the entire side surface of the second chip 200 to protect the first and second chips 100 and 200. For convenience of explanation, the entire structure in which the second chip 200 is stacked on the first chip 100 is referred to as a stacked structure 1100.

Referring to FIG. 21, a molding process for sealing the stacked structure 1100 with a sealant 500 is performed. The molding process may be, for example, an e-MUF process. The e-MUF process may be a process for exposing an upper surface of an uppermost semiconductor chip from a sealant while performing MUF processes for forming both an underfill and the sealant. That is, the e-MUF process may be a process, which does not form the sealant on the upper surface of the uppermost chip when the sealant is injected, by adjusting an internal height of a mold with respect to the upper surface of the uppermost chip. Accordingly, as illustrated in FIG. 22, the upper surface of the second chip 200 may be exposed from the sealant 500 due to the e-MUF process.

In the case of the e-MUF process, the strip substrate 300-S may be pushed up inside a mold for molding so that the upper surface of the uppermost chip (e.g., the second chip 200) of the stacked structure 1100 contacts a lower surface of an inside of the mold for molding, due to the nature of the e-MUF process. Thus, if the gap fill portion 400 exists on the upper surface of the second chip 200, the gap fill portion 400 may bump the mold for molding, and thus, a crack of the second chip 200 may be induced due to the bumping impact.

However, in the method of manufacturing a semiconductor package according to the current example embodiment, the second chip 200 may be maintained to be thicker than the first chip 100 so that the gap fill material layer 400 is not formed on the upper surface of the second chip 200, as described above. Accordingly, the occurrence of a crack of the second chip 200 due to the bump impact between the gap fill portion 400 (e.g., a portion of the gap fill portion 400 remaining on the second chip 200) and the mold for molding in the e-MUF process may be mitigated or prevented.

Referring to FIG. 22, after the sealant 500 for the strip substrate 300-S is formed through a molding process, semiconductor packages 1000 each including a stacked structure 1100 are obtained through a singulation process (e.g., sawing in the direction of an arrow S). As illustrated, external connection members 340 may be disposed on a lower surface of each of the semiconductor package 1000. According to one example embodiment, the external connection members 340 are deposited with respect to the entire strip substrate 300-S, and then each semiconductor package 1000 may be individualized. According to another example embodiment, each semiconductor package 1000 is individualized first, and then the external connection members 340 are deposited on each semiconductor package 1000.

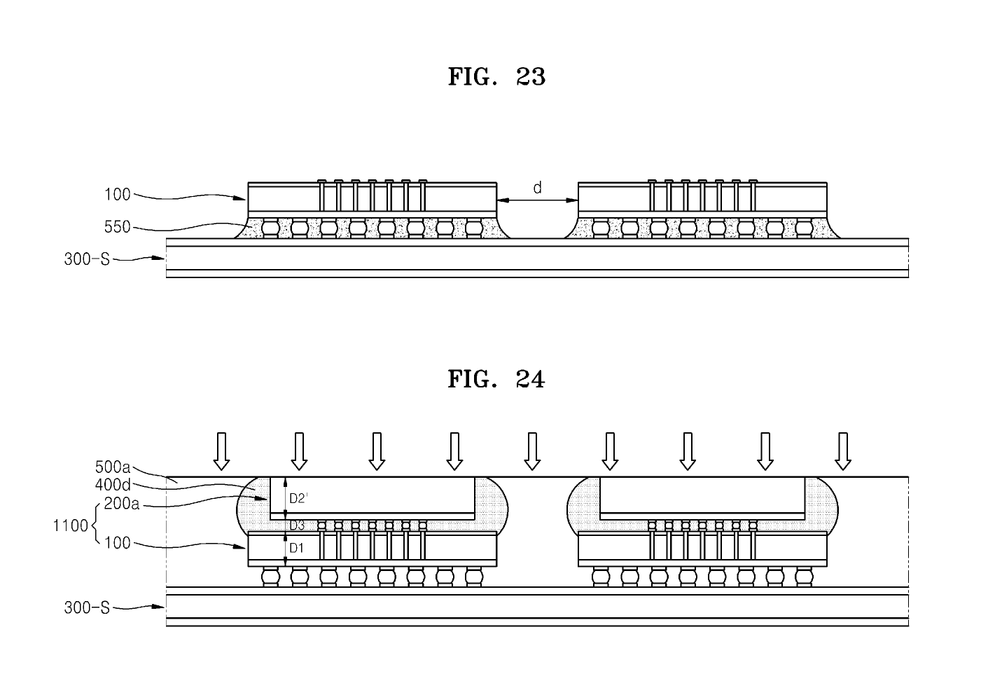

FIG. 23 is a cross-sectional view showing a modification example of the process of FIG. 19 to implement the semiconductor package of FIG. 7, according to an example embodiment of the inventive concepts.

Referring to FIG. 23, after stacking first chips 100 on a strip substrate 300-S as shown in FIG. 19, an underfill 550 may be filled in a space between the first chips 100 and the strip substrate 300-S. An underfill process is a process of filling a space between a chip and a substrate with an underfill resin (e.g., epoxy) by using a capillary phenomenon to improve reliability of a semiconductor package.

After performing such an underfill process, the semiconductor package 1000f as shown in FIG. 7 may be formed by sequentially performing the stacking process of FIG. 20 (i.e., the process including stacking the second chips 200 on the first chips 100), the molding process of FIG. 21, and the singulation process of FIG. 22.

Although the underfill process may be performed after stacking the first chips 100 on the strip substrate 300-S as illustrated in the current example embodiment, the underfill process may be performed after the stacking process of FIG. 20, i.e., after stacking the second chips 200 on the first chips 100.

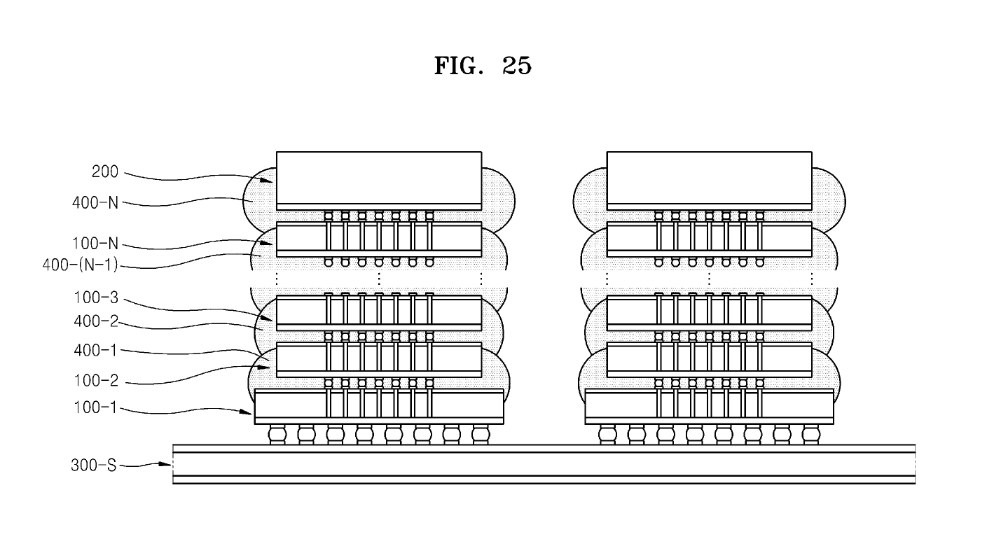

FIG. 24 is a cross-sectional view showing a process that is additionally performed after the process of FIG. 21 to implement the semiconductor package of FIG. 6, according to an example embodiment of the inventive concepts.

Referring to FIG. 24, a grinding process for removing an upper portion of a sealant 500a and an upper portion of a stacked structure 1100 may be performed after performing the molding process of FIG. 21. A thickness of the sealant 500a and a thickness of the second chip 200 of the stacked structure 1100 may be formed relatively small through the grinding process. Further, a gap fill portion 400d may be exposed from the sealant 500a. According to some example embodiments, the gap fill portion 400d may not be exposed from the sealant 500a after the grinding process.

Next, as the singulation process of FIG. 22 is performed, the semiconductor package 1000e having a relatively low height as shown in FIG. 6 may be implemented.

FIG. 25 is a cross-sectional view showing a modification example of the process of FIG. 20 to implement the semiconductor package of FIG. 10 or FIG. 11, according to an example embodiment of the inventive concepts.

Referring to FIG. 25, although in FIG. 20 the second chip 200 is stacked as an uppermost chip on the first chip 100, a plurality of first chips 100-1 through 100-N are sequentially stacked and a second chip 200 is stacked on the sequentially stacked first chips.

For example, a first-first chip 100-1 is stacked on a strip substrate 300-S, and a second-first chip 100-2 is stacked on the first-first chip 100-1. In this manner, N first chips, i.e., the first-first chip 100-1 through a Nth-first chip 100-N, may be sequentially stacked. After the Nth-first chip 100-N is stacked, the second chip 200 may be stacked on the Nth-first chip 100-N. Here, N may be a natural number that is equal to or greater than 3. The first-first chip 100-1 through the Nth-first chip 100-N each may be a chip including a TSV, and the second chip 200 may be a chip that does not include a TSV.

A gap fill portion may be disposed between the first chips (the first-first chip 100-1 through the Nth-first chip 100-N) and between the Nth-first chip 100-N and the second chip 200. For example, a first gap fill portion 400-1 may be disposed between the first-first chip 100-1 and the second-first chip 100-2, a second gap fill portion 400-2 may be disposed between the second-first chip 100-2 and a third-first chip 100-3, an (N−1)th gap fill portion 400-(N−1) may be disposed between the Nth-first chip 100-N and a chip placed thereunder, and an Nth gap fill portion 400-N may be disposed between the Nth-first chip 100-N and the second chip 200.

The first gap fill portion 400-1 through the Nth gap fill portion 400-N may be formed by using the overflow of a gap fill material layer. Accordingly, each gap fill portion may be filled in a space between corresponding chips, and may cover a portion of a side surface of each of corresponding chips or an entire side surface of each of corresponding chips. As illustrated, the side surfaces of the chips 100-2 through 100-N other than the first-first chip 100-1 and the second chip 200 may be covered with the first gap fill portion 400-1 through the Nth gap fill portion 400-N. The overflow of a gap fill material may be adjusted so that the side surface of the first-fist chip 100-1 and the side surface of the second chip 200 may be substantially entirely covered with the first gap fill portion 400-1 and the Nth gap fill portion 400-N, respectively.

After performing a process of stacking the first chips 100-1 through 100-N and the second chip 200, the semiconductor package 100i of FIG. 10 may be formed by performing a molding process and a singulation process. In the current example embodiment, the first-first chip 100-1 may be larger than the other first chips 100-2 through 100-N. However, all the first chips 100-1 through 100-N may have the same size. When all the first chips 100-1 through 100-N have the same size, the semiconductor package 1000j as shown in FIG. 11 may be obtained by performing the molding process and the singulation process.

FIG. 26 is a conceptual diagram showing a principle in which an uppermost chip, which does not include a TSV, is stacked on each chip of an wafer including chips each including a TSV, according to an example embodiment of the inventive concepts.

Referring to FIG. 26, second chips 200 are stacked on a first wafer 100-W. The first wafer 100-W may be a wafer including a plurality of first chips 100 each including a TSV, as described with reference to FIG. 17A. Each of the second chips 200 is a chip that does not include a TSV, and a gap fill material layer may be coated on an lower surface of each second chip 200. The second chip 200 may be obtained through the sawing of the second wafer 200-W as shown in FIG. 17B, which includes a plurality of second chips 200 and of which the lower surface is coated with a gap fill material layer.

The first chips 100 of the first wafer 100-W may have a first thickness D1, and the second chips 200 may have a second thickness D2. The second thickness D2 of the second chips 200 may be larger than the first thickness D1. For example, the second thickness D2 may be a thickness of about 120% to about 300% of the first thickness D1. In FIG. 20, the second chips 200 are stacked on individualized first chips 100, respectively. However, in the current example embodiment, the second chips 200 are stacked on the first chips 100 placed in the first wafer 100-W (i.e., prior to performing an individualization process with regard to the first chips 100), respectively.

In order to stack the second chips 200 on the first chips 100 placed in the first wafer 100-W, the size of the second chips 200 may be smaller than that of the first chips 100. When the size of the second chips 200 is smaller than that of the first chips 100, the second chips 200 may be sufficiently sealed by a sealant (refer to 500in of FIG. 28) in a subsequent process, and further, sawing may be smoothly performed in a subsequent singulation process.

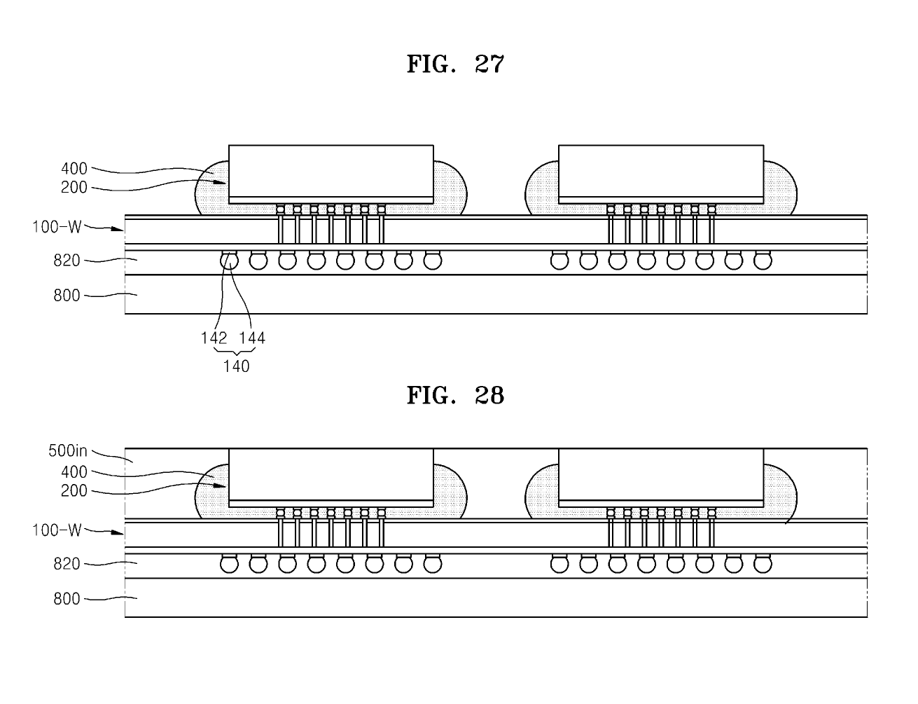

FIGS. 27 through 31 are cross-sectional views showing a method of manufacturing the semiconductor package of FIG. 14, according to an example embodiment of the inventive concepts. FIG. 27 is a cross-sectional view taken along a line III-III′ of FIG. 26 after stacking the second chips 200 on the first wafer 100-W. FIGS. 28 through 31 are cross-sectional views showing processes that are performed after the process of FIG. 27.

Referring to FIG. 27, the first wafer 100-W, which includes a plurality of first chips 100 each including a plurality of TSV 130 formed therein, is attached and fixed onto a support substrate 800 through an adhesive member 820. The support substrate 800 may be formed of, for example, silicon, germanium, silicon-germanium, gallium-arsenide (GaAs), glass, plastic, or ceramic. The adhesive member 820 may be, for example, an NCF, an ACF, an instant adhesive, a thermoset adhesive, a laser-curing adhesive, an ultrasonic curing adhesive, a non-conductive paste (NCP). As illustrated in FIG. 27, the first wafer 100-W may be attached onto the support substrate 800 so that a substrate connection member 140 faces the support substrate 800.

The second chips 200 are stacked on the first chips 100, which are placed in the first wafer 100-W and are fixed onto the support substrate 800. The stacking of the second chips 200 may be performed through a soldering process, and an overflow of a gap fill material layer may be performed on a stacked structure obtained by the stacking. A gap fill portion may be disposed between the first wafer 100-W and each of the second chips 200 by the overflow of the gap fill material layer. The gap fill portion can fill a space between the first wafer 100-W and each of the second chips 200, and may cover a side surface of each of the second chips 200.

Referring to FIG. 28, a first molding process for sealing the second chips 200 with an internal sealant 500in is performed after the second chips 200 are stacked on the first chips 100 placed in the first wafer 100-W. The first molding process may be performed by using, for example, a general molding process or an e-MUF process. In the case of the general molding process, an upper surface of a resultant structure obtained by performing the general molding process may be ground to expose the upper surfaces of the second chips 200 as shown in FIG. 28.

Because in the case of the e-MUF process a gap fill portion 400 is already disposed between the first wafer 100-W and the second chips 200, the e-MUF process may be a little different from the MUF process in which an underfill and a sealant is formed together. For example, the internal sealant 500in formed by using the e-MUF process may expose the upper surfaces of the second chips 200.

As a result, after the internal sealant 500in is formed through the first molding process, the upper surfaces of the second chips 200 may be exposed from the internal sealant 500in.

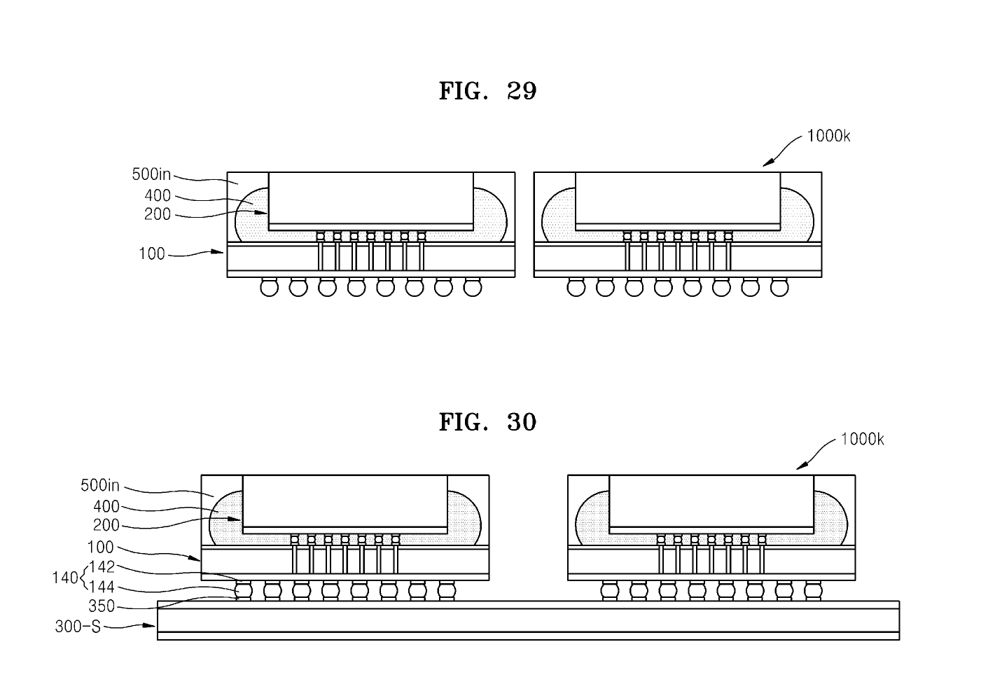

Referring to FIG. 29, after the formation of the internal sealant 500in, the first wafer 100-W, which includes the second chips 200 and the internal sealant 500in, are divided into internal packages 1000k through a singulation process. Each of the internal packages 1000k may include one first chip 100, one second chip 200, and the internal sealant 500in. If the internal sealant 500in is the same as the sealant 500 of FIG. 12, each internal package 1000k may be substantially the same as the semiconductor package 1000k of FIG. 12.

Because a detailed structure of the semiconductor package 1000k of FIG. 12 has been already described above, a detailed description as to a structure of the internal package 1000k is omitted.

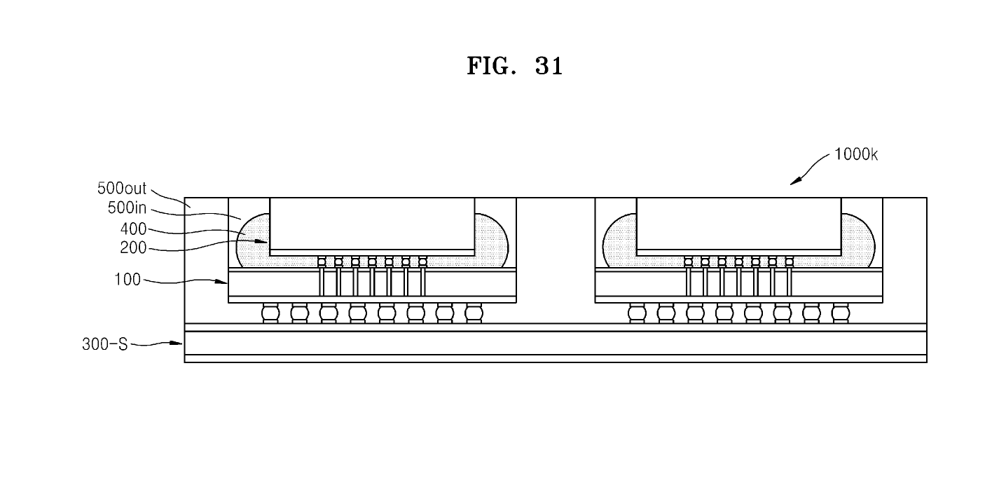

Referring to FIG. 30, the internal packages 1000k are stacked on a strip substrate 300-S. The stacking of the internal packages 1000k may be performed through a soldering process so that a substrate connection member 140 may be coupled to an upper pad 350 on the strip substrate 300-S. According to some example embodiments, an underfill process may be performed between the internal packages 1000k and the strip substrate 300-S.

Referring to FIG. 31, after stacking the internal packages 1000k, a second molding process for sealing the internal packages 1000k with an external sealant 500out is performed. The second molding process may be performed through an e-MUF process. Accordingly, the upper surface of each of the second chips 200 and the internal sealant 500in may be exposed from the external sealant 500out.

The second molding process may be performed through, for example, a general molding process as well as the e-MUF process. When the external sealant 500out is formed through the general molding process, a grinding process may be performed so that the upper surfaces of the second chips 200 and the internal sealant 500in may be exposed from the external sealant 500out.

After the external sealant 500out is formed, the strip substrate 300-S including the internal packages 1000k and external sealant 500out may be divided through a singulation process to form the semiconductor package 1000m of FIG. 14. For example, each semiconductor package 1000m is individualized first, and then external connection members 340 are disposed with respect to the entire strip substrate 300-S. According to another example embodiment, the external connection members 340 are disposed for each semiconductor package 1000m, and then each semiconductor package 1000m is individualized.

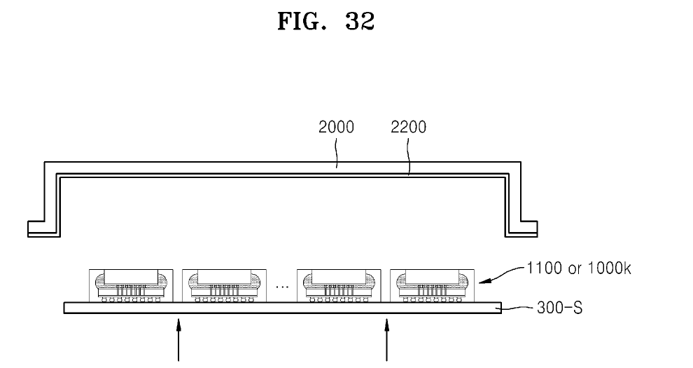

FIG. 32 is a conceptual diagram showing an e-MUF process in a process of manufacturing a semiconductor package according to an example embodiment of the inventive concepts.

Referring to FIG. 32, the e-MUF process is performed after forming a plurality of stacked structure 1100 as shown in FIG. 20 or forming a plurality of internal packages 1000k as shown in FIG. 30, on a strip substrate 300-S. The e-MUF process may be performed by push up the strip substrate 300-S, on which the plurality of stacked structure 1100 or the plurality of internal packages 1000k were stacked, inside a mold 2000 for molding. The molding process includes hermetically closing the mold 2000 and injecting a material for a sealant through a gate.

The e-MUF process may be performed so that an upper surface of an uppermost chip, e.g., the second chip 200, is exposed, and thus, the upper surface of the second chip 200 on the strip substrate 300-S may make a close contact with an internal lower surface of the mold 200 for molding. However, if a material layer such as the gap fill portion 400 remains in an upwardly protruding shape on the upper surface of the second chip 200, an impact may occur between the gap fill portion 400 and the mold 2000 for molding, and thus, a crack of the second chip 200 may be induced as described above. A tape 2200 may be disposed on the internal lower surface of the mold 2000 for molding so that an impact may be alleviated when the upper surfaces of the second chips 200 contact the internal lower surface of the mold 2000 and/or the upper surfaces of the second chips 200 may contact more closely to the internal lower surface of the mold 2000.

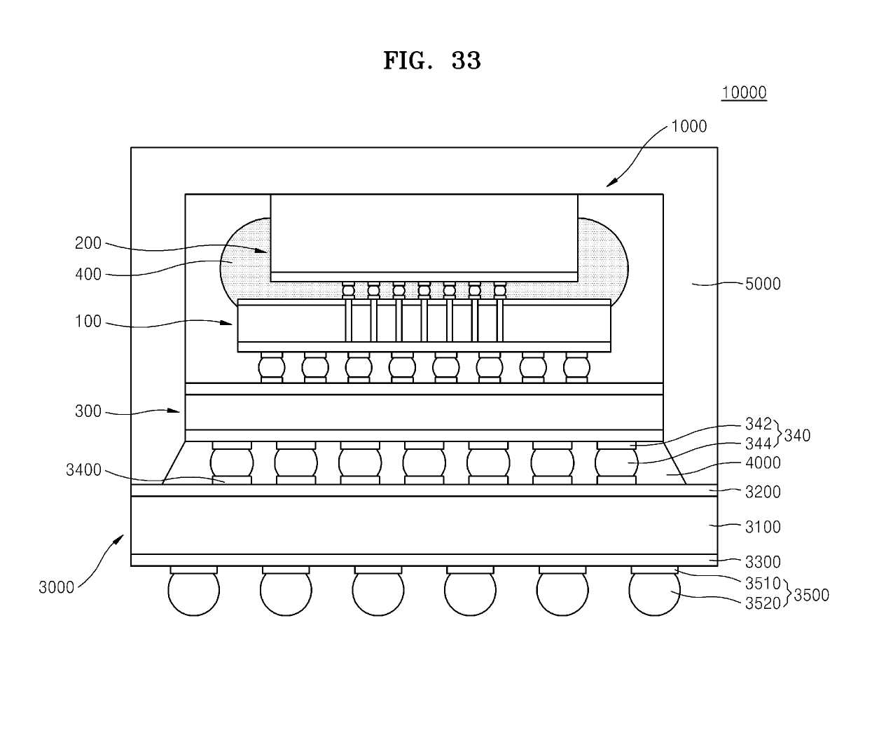

FIG. 33 is a cross-sectional view of a semiconductor package 10000 according to another example embodiment of the inventive concepts.

Referring to FIG. 33, a semiconductor package 10000 may include a board substrate 3000, an upper semiconductor package 1000, an underfill 4000, and an external sealant 5000.

The structure of the upper semiconductor package 1000 may be substantially the same as that of the semiconductor package 1000 of FIG. 1. However, structures of the upper semiconductor package 1000 are not limited to that of the semiconductor package 1000 of FIG. 1, and may be replaced with any one of the semiconductor packages of FIGS. 2 through 14. In the upper semiconductor package 1000, a substrate 300 may be any one of a PCB, an interposer, and a chip that is different from the first chips described above.

Because the upper semiconductor package 1000 is substantially the same as the semiconductor package 1000 of FIG. 1, detailed descriptions of components of the upper semiconductor package 1000 are omitted. The upper semiconductor package 1000 may be mounted on the board substrate 3000 through an external connection member 340.

The board substrate 3000 may include a body layer 3100, an upper protection layer 3200, a lower protection layer 3300, an upper pad 3400, and a connection member 3500. A plurality of interconnection patterns may be formed in the body layer 3100. The upper protection layer 3200 and the lower protection layer 3300 have a function of protecting the body layer 3100, and may be a solder resist. The board substrate 3000 may be standardized, and may have a limit in reducing the size thereof.

The external sealant 5000 may seal side and upper surfaces of the upper semiconductor package 1000, and the lower surface of the external sealant 5000 may adhere to an edge portion of the board substrate 3000. The underfill 4000 may fill a connection portion between the upper semiconductor package 1000 and the board substrate 3000. In the current example embodiment, although the underfill 4000 is formed in the connection portion between the upper semiconductor package 1000 and the board substrate 3000, the underfill 4000 may be omitted if the external sealant 5000 is formed through an MUF process.

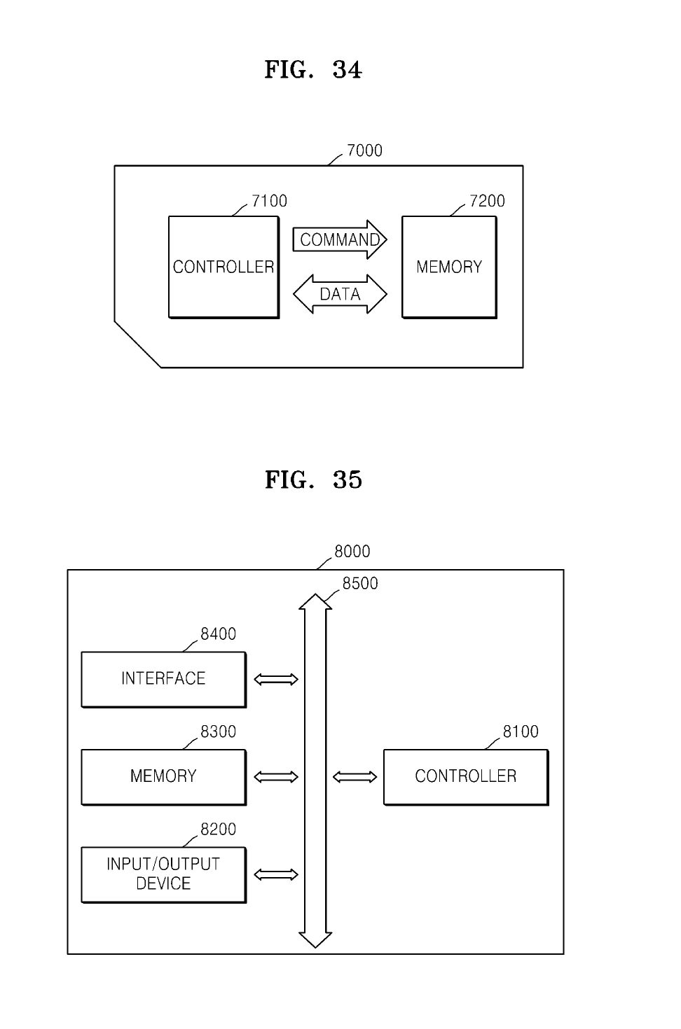

FIG. 34 is a block diagram of a memory card 7000 including a semiconductor package according to one or more example embodiments of the inventive concepts.

Referring to FIG. 34, in the memory card 7000, a controller 7100 and a memory 7200 may be arranged so as to exchange electrical signals. For example, when the controller 7100 sends a command, the memory 7200 may send data. The controller 7100 and/or the memory 7200 may include a semiconductor package according to any one of example embodiments of the inventive concepts. The memory 7200 may include, for example, a memory array (not shown) or a memory array bank (not shown).

The memory card 7000 may be used for various memory apparatuses, for example, various types of cards (e.g., a memory stick card, a smart media (SM) card, a secure digital (SD) card, a mini SD card, and a multi-media card (MMC)).

FIG. 35 is a block diagram of an electronic system 8000 including a semiconductor package according to one or more example embodiments of the inventive concepts.

Referring to FIG. 35, the electronic system 8000 may include a controller 8100, an input/output device 8200, a memory 8300, and an interface 8400. The electronic system 8000 may be, for example, a mobile system or a system for transmitting or receiving information. The mobile system may be, for example, a personal digital assistant (PDA), a portable computer, a web tablet, a wireless phone, a mobile phone, a digital music player, or a memory card.

The controller 8100 may function to execute a program and to control the electronic system 8000. The controller 8100 may be, for example, a microprocessor, a digital signal processor, a microcontroller, or a similar device. The input/output device 8200 may be used to input or output data into or from the electronic system 8000.

The electronic system 8000 may exchange data with an external device, e.g., a personal computer (PC) or a network, by connecting to the external device using the input/output device 8200. The input/output device 8200 may be, for example, a keypad, a keyboard, or a display. The memory 8300 may store codes and/or data for an operation of the controller 8100 and/or store data processed by the controller 8100. The controller 8100 and the memory 8300 may include the semiconductor package according to any one of example embodiments of the inventive concepts. The interface 8400 may be a data transmission path between the electronic system 8000 and an external device. The controller 8100, the input/output device 8200, the memory 8300, and the interface 8400 may communicate with each other via a bus 8500.

For example, the electronic system 8000 may be used for mobile phones, MP3 players, navigation machines, portable multimedia players (PMPs), solid state disks (SSDs), and household appliances.

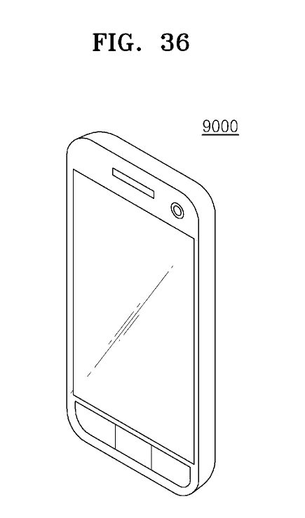

FIG. 36 is a perspective view of an electronic device to which a semiconductor package according to one or more embodiments of the inventive concepts is applied.

FIG. 36 is an example in which the electronic system 8000 of FIG. 35 is applied to a mobile phone 9000. Besides, the electronic system 8000 may be applied to portable laptop computers, MP3 players, navigation machines, SSDs, vehicles, and household appliances.

While the inventive concepts have been particularly shown and described with reference to some example embodiments thereof, it will be understood that various changes in form and details may be made therein without departing from the spirit and scope of the following claims.

1. A semiconductor package comprising:
a substrate;
a first chip on the substrate, the first chip including a plurality of through silicon vias (TSVs);
an uppermost chip on the first chip, a thickness of the uppermost chip being larger than that of the first chip;
a first gap fill portion covering at least a portion of a side surface of the uppermost chip while filling a space between the first chip and the uppermost chip; and
a sealant for sealing the first chip, the uppermost chip, and the first gap fill portion.

2. The semiconductor package of claim 1, wherein the first gap fill portion covers at least a portion of a side surface of the first chip.

3. The semiconductor package of claim 1, wherein the first gap fill portion does not exist on an upper surface of the uppermost chip.

4. (canceled)

5. The semiconductor package of claim 1, further comprising:
a plurality of pads on an upper surface of the first chip, the plurality of pads electrically connected to the TSVs; and
a plurality of connection members on a lower surface of the uppermost chip, the plurality of connection members coupled to the plurality of pads,
wherein the first gap fill portion fills a space between the plurality of connection members.

6. The semiconductor package of claim 1, wherein the uppermost chip does not include a TSV.

7. (canceled)

8. The semiconductor package of claim 1, wherein
a horizontal cross section of the first chip is larger than that of the uppermost chip, and
the first gap fill portion covers an upper surface of an edge portion of the first chip, and the edge portion protrudes from the side surface of the uppermost chip.

9. The semiconductor package of claim 1, wherein
the first chip is stacked on the substrate through a substrate connection member, and
a space between the first chip and the substrate is filled with at least one of an underfill and the sealant.

10. The semiconductor package of claim 1, further comprising:
at least one second chip between the first chip and the uppermost chip, the at least one second chip including a plurality of TSVs.

11. The semiconductor package of claim 10, wherein a space between the first chip and the second chip is filled with a second gap fill portion, and the second gap fill portion covers at least a portion of at least one of a side surface of the first chip and a side surface of the at least one second chip.

12. (canceled)

13. A semiconductor package comprising:
a first chip including a plurality of through silicon vias (TSVs);
a plurality of first connection members on a lower surface of the first chip and electrically connected to the TSVs;
an uppermost chip on the first chip;
a second connection member on a lower surface of the uppermost chip and coupled to the TSVs, a thickness of the uppermost chip being larger than that of the first chip;
a first gap fill portion covering at least a portion of a side surface of the uppermost chip while filling a space between the first chip and the uppermost chip; and
a sealant for sealing the first chip, the uppermost chip, and the first gap fill portion.

14. The semiconductor package of claim 13, wherein
a horizontal cross section of the first chip is larger than that of the uppermost chip, and
the first gap fill portion covers an upper surface of an edge portion of the first chip, and the edge portion protrudes from the side surface of the uppermost chip.

15. The semiconductor package of claim 13, wherein
an upper surface of the uppermost chip is exposed by the sealant, the sealant covers at least a portion of at least one of the side surface of the uppermost chip and a side of the first chip, and
a lower surface of the sealant forms substantially a same plane as a lower surface of the first chip.

16. The semiconductor package of claim 13, further comprising:
at least one second chip between the first chip and the uppermost chip, the at least one second chip including a plurality of TSVs,
wherein a space between the first chip and the second chip is filled with a second gap fill portion, and the second gap fill portion covers at least a portion of at least one of a side surface of the first chip and a side surface of the at least one second chip

17. The semiconductor package of claim 13, further comprising:
a base substrate including an external connection member on a lower surface thereof, the base substrate having the first chip and the uppermost chip mounted thereon through the plurality of first connection members.

18. The semiconductor package of claim 17, wherein
a size of the base substrate is larger than that of the first chip, and
a lower surface of the sealant is joined onto an edge portion of the base substrate.

19.-25. (canceled)

26. A semiconductor package comprising:
first chips stacked on each other, each of the first chips including a plurality of through silicon vias (TSVs);
at least one second chip on the first chips;
a gap fill portion covering at least a portion of a side surface of the at least one second chip and not covering an upper surface of the at least one second chip; and
a sealant for sealing the first chips, the at least one second chip, and the gap fill portion.

27. The semiconductor package of claim 26, wherein the at least one second chip is thicker than one of the first chips immediately below.

28. The semiconductor package of claim 26, wherein the at least one second chip has a cut-out shaped upper surface, and the cut-out shaped upper surface is configured to be coplanar with an upper surface of the sealant and exposed by the sealant.

29. The semiconductor package of claim 26, further comprising:
a heat sink coupled to the at least one second chip at on an upper surface thereof.

30. The semiconductor package of claim 29, wherein
a horizontal cross section of some of the first chips is larger than that of the at least one second chip.
